(19) United States
(12) Patent Application Publication
(10) Pub. No.: US 2025/0299734 A1
(43) Pub. Date: Sep. 25, 2025

(54) MEMORY DEVICE

(71) Applicant: Kioxia Corporation, Tokyo (JP)

(72) Inventor: Manabu Sato, Chigasaki Kanagawa (JP)

(73) Assignee: Kioxia Corporation, Tokyo (JP)

(21) Appl. No.: 18/980,715

(22) Filed: Dec. 13, 2024

(30) Foreign Application Priority Data
Mar. 21, 2024 (JP) 2024-045424

(51) Int. Cl. G11C 16/04; G11C 5/06; G11C 16/08; G11C 16/30

(52) U.S. Cl. CPC G11C 16/0483; G11C 5/06; G11C 16/08; G11C 16/30

(57) ABSTRACT

According to one embodiment, a memory device includes a first block including a first memory string having a first transistor at an end, a second transistor having a first end connected to a gate of the first transistor, first interconnect connected to a gate of the second transistor, a block decoder connected to one end of the first interconnect, a third transistor having a first end connected to the other end of the first interconnect, and a power supply connected to a second end of the third transistor.

### CROSS-REFERENCE TO RELATED APPLICATION

This application is based upon and claims the benefit of priority from Japanese Patent Application No. 2024-045424, filed Mar. 21, 2024, the entire contents of which are incorporated herein by reference.

### FIELD

Embodiments described herein relate generally to a memory device.

### BACKGROUND

A NAND flash memory is known as a memory device capable of storing data in a nonvolatile manner. Memory devices such as a NAND flash memory employ a three-dimensional memory structure for high integration and large capacity. Large-capacity memory devices are required to detect in advance a defective memory area due to a disconnection or the like and thus to prevent the defective memory area from affecting the operation of the devices.

### BRIEF DESCRIPTION OF THE DRAWINGS

FIG. 1 is a block diagram showing a configuration of a memory system including a memory device according to a first embodiment.

FIG. 2 is a circuit diagram showing an example of a circuit configuration of a memory cell array according to the first embodiment.

FIG. 3 is a circuit diagram showing an example of connection of a row decoder module and its peripheral circuits according to the first embodiment.

FIG. 4 is a circuit diagram showing an example of a circuit configuration of the row decoder module according to the first embodiment.

FIG. 5 is a plan view showing an example of a planar layout of a row decoder according to the first embodiment.

FIG. 6 is a timing chart showing a first example of a broken wire detection operation in the memory device according to the first embodiment.

FIG. 7 is a timing chart showing a second example of the broken wire detection operation in the memory device according to the first embodiment.

FIG. 8 is a timing chart showing a third example of the broken wire detection operation in the memory device according to the first embodiment.

FIG. 9 is a graph showing an example of a resistance measuring operation in the memory device according to the first embodiment.

FIG. 10 is a circuit diagram showing an example of a configuration of a memory cell array according to a second embodiment.

FIG. 11 is a circuit diagram showing an example of connection of a row decoder module and its peripheral circuits according to the second embodiment.

FIG. 12 is a plan view showing an example of a planar layout of a row decoder module in a memory device according to the second embodiment.

FIG. 13 is a circuit diagram showing an example of connection of a row decoder module and its peripheral circuits according to a third embodiment.

FIG. 14 is a plan view showing an example of a planar layout of a row decoder module in a memory device according to the third embodiment.

FIG. 15 is a circuit diagram showing an example of connection of a row decoder module and its peripheral circuits according to a fourth embodiment.

FIG. 16 is a plan view showing an example of a planar layout of a row decoder module in a memory device according to the fourth embodiment.

FIG. 17 is a circuit diagram showing an example of a circuit configuration of a row decoder module according to a first modification.

FIG. 18 is a circuit diagram showing an example of a circuit configuration of a row decoder module according to a second modification.

### DETAILED DESCRIPTION

In general, according to one embodiment, a memory device includes a first block including a first memory string having a first transistor at an end, a second transistor having a first end connected to a gate of the first transistor, first interconnect connected to a gate of the second transistor, a block decoder connected to one end of the first interconnect, a third transistor having a first end connected to the other end of the first interconnect, and a power supply connected to a second end of the third transistor.

Embodiments will be described below with reference to the drawings. The dimensions and ratios of the drawings are not necessarily the same as the actual ones.

In the following description, components having substantially the same or similar function and configuration are denoted by the same reference symbol. To distinguish components having the same or similar configuration specifically, different letters or numerals may be added to the end of the same reference symbol.

Assume in the present specification that if there is symbol X to the end of which “n” is added, a voltage level, which is inverted to a voltage level applied to the configuration corresponding to symbol X, is applied to the configuration corresponding to symbol Xn. That is, signal Xn is an inverted signal of signal X.

In the present specification, “node” may be read as “interconnect.” The “logical level of a node” may be read as the “logical level of a signal supplied to interconnect.”

### 1. First Embodiment

A first embodiment will be described.

### 1. 1 Configuration

A configuration according to the first embodiment will be described.

### 1. 1. 1 Memory System

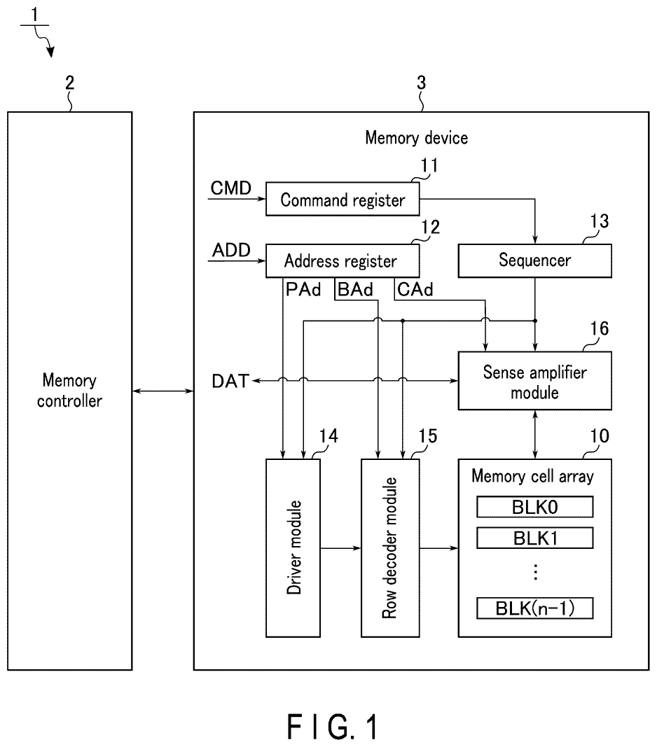

FIG. 1 is a block diagram showing an example of a configuration of a memory system 1 including a memory device according to the first embodiment. The memory system 1 is a storage device configured to be connected to an external host (not shown). The memory system 1 is, for example, a memory card such as an SD™ card, a universal flash storage (UFS), and a solid state drive (SSD). The memory system 1 includes a memory controller 2 and a memory device 3.

The memory controller 2 is configured by an integrated circuit such as a system-on-a-chip (SoC). The memory controller 2 controls the memory device 3 based on a request from the host. Specifically, for example, the memory controller 2 writes data to the memory device 3 at the request of the host. The memory controller 2 also reads data from the memory device 3 at the request of the host and then transmits the data to the host.

The memory device 3 is a nonvolatile memory. The memory device 3 is, for example, a NAND flash memory. The memory device 3 stores data in a nonvolatile manner.

Communications between the memory controller 2 and the memory device 3 are based on a single data rate (SDR) interface, a toggle double data rate (DDR) interface, an open NAND flash interface (ONFI), or the like.

### 1. 1. 2 Memory Device

The internal configuration of the memory device 3 according to the first embodiment will be described with reference to the block diagram shown in FIG. 1. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLK(n−1), where n is an integer of 2 or more. The number of blocks BLK included in the memory cell array 10 may be one. The blocks BLK are a set of memory cells. The blocks BLK are each used as, for example, an erase unit of data. The memory cell array 10 also includes a plurality of bit lines and a plurality of word lines. Each of the memory cells is associated with, for example, one bit line and one word line. The configuration of the memory cell array 10 will be described in detail later.

The command register 11 stores a command CMD that is received by the memory device 3 from the memory controller 2. The command CMD includes, for example, instructions for causing the sequencer 13 to execute a variety of operations including a read operation, a write operation, an erase operation, and the like.

The address register 12 stores address information ADD that is received by the memory device 3 from the memory controller 2. The address information ADD includes, for example, a block address BAd, a page address PAd, and a column address CAd. The block address BAd, page address PAd and column address CAd are, for example, used to select a block BLK, a word line and a bit line, respectively.

The sequencer 13 controls the entire operation of the memory device 3. For example, in response to the command CMD stored in the command register 11, the sequencer 13 controls the driver module 14, row decoder module 15 and sense amplifier module 16, and the like to perform a read operation, a write operation, an erase operation, and the like.

The driver module 14 generates a voltage to be used in the read operation, write operation, erase operation, and the like. Then, the driver module 14 applies the generated voltage to a signal line corresponding to a selected word line, based on the page address PAd stored in the address register 12, for example.

Based on the block address BAd stored in the address register 12, the row decoder module 15 selects its corresponding one of the block BLKs in the memory cell array 10. Then, the row decoder module 15 transfers, for example, the voltage applied to the signal line corresponding to the selected word line, to the selected word line in the selected one of the blocks BLK.

In the write operation, the sense amplifier module 16 applies a desired voltage to each bit line in accordance with the write data DAT received from the memory controller 2. In the read operation, the sense amplifier module 16 determines the data stored in the memory cell based on the voltage of the bit line, and transfers a result of the determination to the memory controller 2 as read data DAT.

### 1. 1. 3 Memory Cell Array

Next is a description of a configuration of the memory cell array 10 according to the first embodiment.

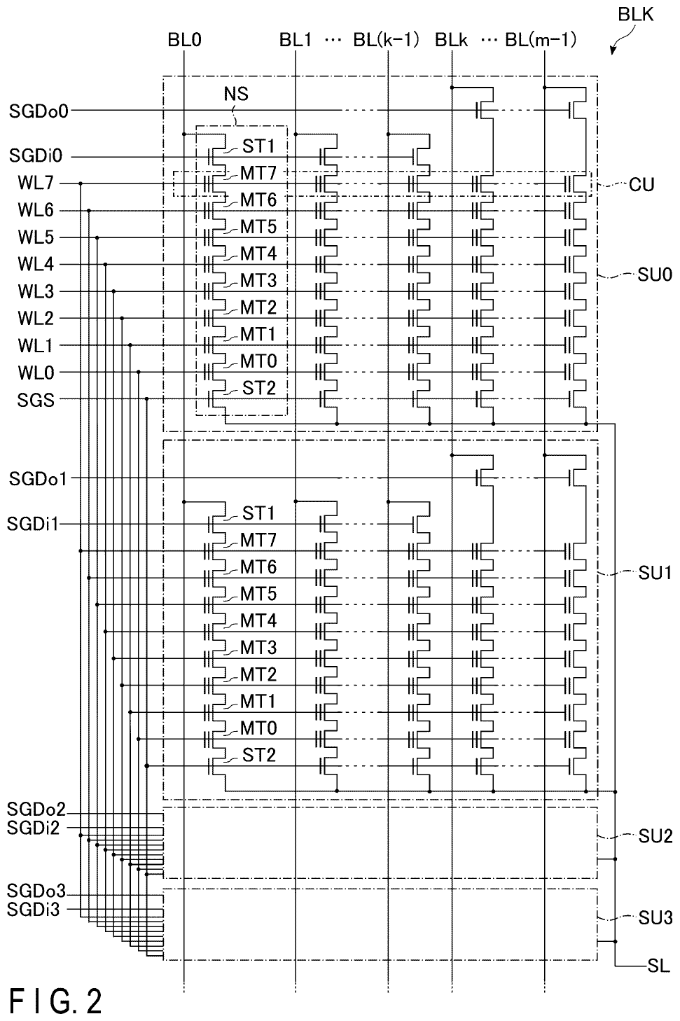

FIG. 2 is a circuit diagram showing an example of a circuit configuration of the memory cell array 10 according to the first embodiment. FIG. 2 shows one block BLK among a plurality of blocks BLK included in the memory cell array 10. As shown in FIG. 2, the block BLK includes, for example, four string units SU0 to SU3.

Each of the string units SU0 to SU3 includes a plurality of NAND strings NS which are associated with each of bit lines BL0 to BL(k−1) and BL(k) to BL(m−1) (k is an integer greater than or equal to 1, m is an integer greater than or equal to 2, and k=m/2 in the normal configuration). The number of bit lines BL may be two to four. Each NAND string NS includes, for example, memory cell transistors MT0 to MT7 and selection transistors ST1 and ST2. Each memory cell transistor MT includes a control gate and a charge storage film to store data in a nonvolatile manner. Each of the selection transistors ST1 and ST2 is used to select a string unit SU in a variety of operations.

In each NAND string NS, the memory cell transistors MT0 to MT7 are connected in series. The drain of the selection transistor ST1 is connected to its associated bit line BL. The source of the selection transistor ST1 is connected to one end of the series-connected memory cell transistors MT0 to MT7. The drain of the selection transistor ST2 is connected to the other end of the series-connected memory cell transistors MT0 to MT7. The source of the selection transistor ST2 is connected to a source line SL.

In the same block BLK, the control gates of the memory cell transistors MT0 to MT7 are connected to their respective word lines WL0 to WL7. Among the selection transistors ST1 in the string units SU0 to SU3, the gates of the selection transistors ST1 connected to the bit lines BL0 to BL(k−1) are connected to their respective selection gate lines SGDi0 to SGDi3. Among the selection transistors ST1 in the string units SU0 to SU3, the gates of the selection transistors ST1 connected to the bit lines BLk to BL(m−1) are connected to their respective selection gate lines SGDo0 to SGDo3. The gates of the selection transistors ST2 in the string units SU0 to SU3 are connected to a selection gate line SGS.

The bit lines BL0 to BL(m−1) are assigned different column addresses. Each bit line BL is shared by NAND strings NS that are assigned the same column address among a plurality of blocks BLK. The word lines WL0 to WL7 are provided for each block BLK. The source line SL is shared among a plurality of blocks BLK, for example.

A set of memory cell transistors MT connected to a common word line WL in a single string unit SU is referred to as, for example, a cell unit CU. The storage capacity of a cell unit CU including memory cell transistors MT each of which stores one-bit data is defined as, for example, “one-page data.” The cell unit CU may have a storage capacity of two-page data or more in accordance with the number of bits of data stored in the memory cell transistors MT.

Note that the circuit configuration of the memory cell array 10 included in the memory device 3 according to the first embodiment is not limited to the configuration described above. For example, the number of string units SU included in each block BLK can be designed to be an any number. The number of memory cell transistors MT included in each NAND string NS can be designed to be an any number, as can be the number of selection transistors ST1 and ST2 included therein.

### 1. 1. 4 Row Decoder Module

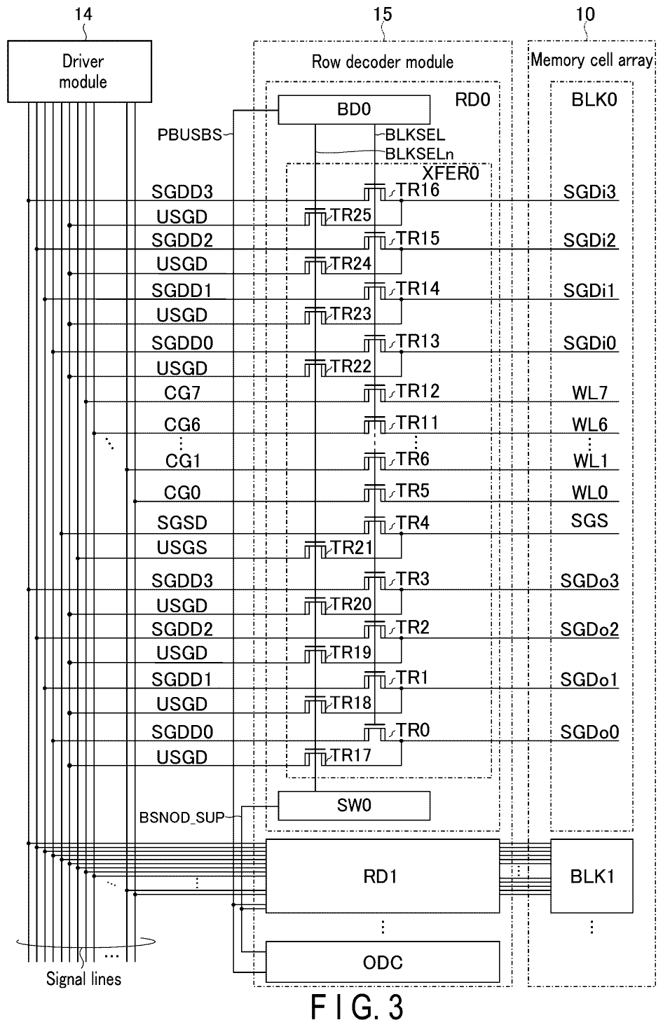

FIG. 3 is a circuit diagram showing an example of connection of a row decoder module and its peripheral circuits according to the first embodiment. As shown in FIG. 3, the row decoder module 15 includes a plurality of row decoders RD (RD0, RD1, . . . ) and a disconnection detection circuit ODC. The number of row decoders RD corresponds to the number of blocks BLK. In the example of FIG. 3, the configuration of the row decoder RD0 corresponds to the block BLK0. The row decoder RD0 includes a block decoder BD0, a transfer switch XFER0 and a disconnection detection switch SW0.

The row decoders RD have an equivalent configuration. The configuration of the row decoder RD corresponding to a certain block BLK will be described below with reference to FIG. 3.

### 1. 1. 4. 1 Transfer Switch

First, the configuration of a transfer switch XFER will be described with reference to FIG. 3.

The transfer switch XFER includes 26 transistors TR0 to TR25. Each of the transistors TR0 to TR25 is an N-type transistor, for example.

The first ends of the transistors TR0, TR1, TR2 and TR3 are connected to their corresponding blocks BLK via their respective selection gate lines SGDo0, SGDo1, SGDo2 and SGDo3. The second ends of the transistors TR0, TR1, TR2, and TR3 are connected to the driver module 14 via their respective interconnects SGDD0, SGDD1, SGDD2 and SGDD3. The gate of each of the transistors TR0, TR1, TR2 and TR3 is connected to its corresponding block decoder BD via interconnect BLKSEL.

The first end of the transistor TR4 is connected to its corresponding block BLK via the selection gate line SGS. The second end of the transistor TR4 is connected to the driver module 14 via interconnect SGSD. The gate of the transistor TR4 is connected to its corresponding block decoder BD via the interconnect BLKSEL.

The first ends of the transistors TR5 to TR12 are connected to their corresponding blocks BLK via the word lines WL0 to WL7, respectively. The second ends of the transistors TR5 to TR12 are connected to the driver module 14 via their respective interconnects CG0 to CG7. The gate of each of the transistors TR5 to TR12 is connected to its corresponding block decode BD via the interconnect BLKSEL.

The first ends of the transistors TR13, TR14, TR15 and TR16 are connected to their corresponding blocks BLK via their respective selection gate lines SGDi0, SGDi1, SGDi2 and SGDi3. The second ends of the transistors TR13, TR14, TR15 and TR16 are connected to the driver module 14 via their respective interconnects SGDD0, SGDD1, SGDD2 and SGDD3. The gate of each of the transistors TR13, TR14, TR15 and TR16 is connected to its corresponding block decoder BD via the interconnect BLKSEL.

For example, the transistors TR5 to TR12 may transfer a write voltage VPGM to their respective word lines WL0 to WL7 in a write operation and transfer a read voltage VREAD thereto in a read operation. The write voltage VPGM is high enough to raise the threshold voltage of the memory cell transistor MT. The read voltage VREAD is a high voltage that turns on the memory cell transistor MT, regardless of the threshold voltage of the memory cell transistor MT. Thus, the gates of the transistors TR0 to TR16 are supplied, via the interconnect BLKSEL, with a voltage VPGMH that is higher than the write voltage VPGM and a voltage VREADH that is higher than the read voltage VREAD. Therefore, the transistors TR0 to TR16 are designed to have a withstand voltage that is high enough to allow a normal operation to be operated with the voltages VPGMH and VREADH applied. Hereinafter, a transistor having a withstand voltage that is high enough to allow a normal operation to be performed with the voltages VPGMH and VREADH applied, will also be referred to a “high withstand voltage transistor.” The high withstand voltage transistor is so designed that the thickness of the gate oxide film is about 40 nm if it can be operated up to 30 V, for example. In contrast, a transistor having a withstand voltage that is lower than that of the high withstand voltage transistor will also be referred to as a “low withstand voltage transistor” or simply as a “transistor.” The low withstand voltage transistor is so designed that the thickness of the gate oxide film is, for example, 5 nm or more and 7 nm or less.

Transistors TR17, TR18, TR19 and TR20 are also high withstand voltage transistors. The first ends of the transistors TR17, TR18, TR19 and TR20 are connected to their corresponding blocks BLK via their respective selection gate lines SGDo0, SGDo1, SGDo2 and SGDo3. The second ends of the transistors TR17, TR18, TR19 and TR20 are connected to the driver module 14 via interconnect USGD. The gates of the transistors TR17, TR18, TR19 and TR20 are connected to their corresponding block decoders BD and disconnection detection switches SW via interconnect BLKSELn.

Transistor TR21 is also a high withstand voltage transistor. The first end of the transistor TR21 is connected to its corresponding block BLK via the selection gate line SGS. The second end of the transistor TR21 is connected to the driver module 14 via interconnect USGS. The gate of the transistor TR21 is connected to its corresponding block decoder BD and disconnection detection switch SW via the interconnect BLKSELn.

Transistors TR22, TR23, TR24 and TR25 are also high withstand voltage transistors. The first ends of the transistors TR22, TR23, TR24 and TR25 are connected to their corresponding blocks BLK via their respective selection gate lines SGDi0, SGDi1, SGDi2 and SGDi3. The second end of each of the transistors TR22, TR23, TR24 and TR25 is connected to the driver module 14 via the interconnect USGD. The gates of the transistors TR22, TR23, TR24 and TR25 are connected to their corresponding block decoders BD and disconnection detection switches SW via the interconnect BLKSELn.

The disconnection detection circuit ODC is connected to a plurality of block decoders BD which respectively correspond to the blocks BLK via interconnect PBUSBS. The disconnection detection circuit ODC is connected to a plurality of disconnection detection switches SW corresponding to their respective blocks BLK, via interconnect BSNOD_SUP.

### 1. 1. 4. 2 Block Decoder, Disconnection Detection Switch and Disconnection Detection Circuit

Next is a description of configurations of the block decoder BD, disconnection detection switch SW and disconnection detection circuit ODC.

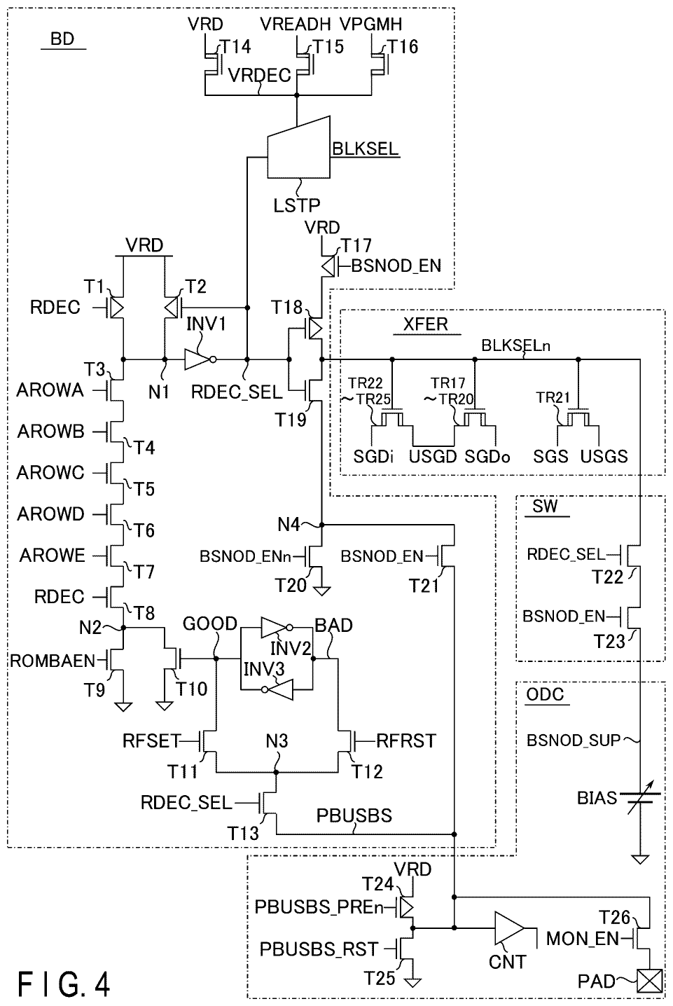

FIG. 4 is a circuit diagram showing an example of a circuit configuration of the row decoder module according to the first embodiment. FIG. 4 shows a block decoder BD, part of a transfer switch XFER, a disconnection detection switch SW, and a disconnection detection circuit ODC in a row decoder RD corresponding to a certain block BLK.

First, the configuration of the block decoder BD will be described.

The block decoder BD includes transistors T1 to T21, inverters INV1 to INV3 and a level shifter LSTP. The transistors T1, T2, T17 and T18 are, for example, P-type transistors. The transistors T3 to T16 and T19 to T21 are, for example, N-type transistors.

The transistor T1 has a first end to which a voltage VRD is applied, a second end connected to a node N1, and a gate connected to a node RDEC. The transistor T2 has a first end to which the voltage VRD is applied, a second end connected to the node N1, and a gate connected to the node RDEC_SEL. The voltage VRD corresponds to, for example, an “H” level logic level in the row decoder RD.

The inverter INV1 has an input end connected to the node N1 and an output end connected to the node RDEC_SEL. That is, the inverter INV1 inverts the logic level of the node N1 and outputs it to the node RDEC_SEL.

The transistor T3 has a first end connected to the node N1 and a gate connected to a node AROWA. The transistor T4 has a first end connected to a second end of the transistor T3 and a gate connected to a node AROWB. The transistor T5 has a first end connected to a second end of the transistor T4 and a gate connected to a node AROWC. The transistor T6 has a first end connected to a second end of the transistor T5 and a gate connected to a node AROWD. The transistor T7 has a first end connected to a second end of the transistor T6 and a gate connected to a node AROWE.

The transistor T8 has a first end connected to a second end of the transistor T7, a second end connected to a node N2, and a gate connected to the node RDEC. The transistor T9 has a first end connected to the node N2, a second end to be grounded, and a gate connected to a node ROMBAEN. Assume hereinafter that the ground voltage will be a voltage VSS. The voltage VSS is, for example, 0 V.

The transistor T10 has a first end connected to the node N2, a second end to be grounded, and a gate connected to a node GOOD. The transistor T11 has a first end connected to the node GOOD, a second end connected to a node N3, and a gate connected to a node RFSET. The transistor T12 has a first end connected to a node BAD, a second end connected to the node N3, and a gate connected to the node RFRST. The transistor T13 has a first end connected to the node N3, a second end connected to the interconnect PBUSBS, and a gate connected to the node RDEC_SEL.

The inverter INV2 has an input end connected to the node GOOD and an output end connected to the node BAD. That is, the inverter INV2 inverts the logic level of the node GOOD and outputs it to the node BAD. The inverter INV3 has an input end connected to the node BAD and an output end connected to the node GOOD. That is, the inverter INV3 inverts the logic level of the node BAD and outputs it to the node GOOD.

If the block BLK is in a good state, the logic level of the node GOOD and that of the node BAD are “H” and “L,” respectively. If the block BLK is in a bad state, the logic level of the node GOOD and that of the node BAD are “L” and “H,” respectively.

The transistor T14 is a high withstand voltage transistor having a first end to which the voltage VRD is applied and a second end connected to a node VRDEC. The transistor T15 is a high withstand voltage transistor having a first end to which a voltage VREADH is applied and a second end connected to the node VRDEC. The transistor T16 is a high withstand voltage transistor having a first end to which a voltage VPGMH is applied and a second end connected to the node VRDEC. The level shifter LSTP includes an input end connected to the node RDEC_SEL, an output end connected to the interconnect BLKSEL, and a control end connected to the node VRDEC. The level shifter LSTP is configured to amplify a voltage input from the node RDEC_SEL and supply the amplified voltage to the interconnect BLKSEL in accordance with the level of a voltage applied to the node VRDEC via any one of the transistors T14, T15 and T16.

The transistor T17 has a first end to which the voltage VRD is applied and a gate connected to a node BSNOD_EN. The transistor T18 has a first end connected to a second end of the transistor T17, a second end connected to one end of the interconnect BLKSELn, and a gate connected to the node RDEC_SEL. The transistor T19 has a first end connected to the one end of the interconnect BLKSELn, a second end connected to a node N4, and a gate connected to the node RDEC_SEL. The transistor T20 has a first end connected to the node N4, a second end to be grounded, and a gate connected to a node BSNOD_ENn. The transistor T21 has a first end connected to the node N4, a second end connected to the interconnect PBUSBS, and a gate connected to the node BSNOD_EN. The transistors T17 to T21 constitute an inverter. If, therefore, the transistors T17 to T21 function as an inverter, they invert the logic level of the node RDEC_SEL and output it to the interconnect BLKSELn.

Next is a description of a configuration of the disconnection detection switch SW.

The disconnection detection switch SW includes transistors T22 and T23. The transistors T22 and T23 are, for example, N-type transistors.

The transistor T22 has a first end connected to the other end of the interconnect BLKSELn and a gate connected to the node RDEC_SEL. The transistor T23 has a first end connected to a second end of the transistor T22, a second end connected to the interconnect BSNOD_SUP, and a gate connected to the node BSNOD_EN. Note that the transistor T22 may not be provided and, in this case, the transistor T23 has a first end connected to the other end of the interconnect BLKSELn, a second end connected to the interconnect BSNOD_SUP, and a gate connected to the node BSNOD_EN.

Next is a description of a configuration of the disconnection detection circuit ODC.

The disconnection detection circuit ODC includes transistors T24, T25 and T26, a control circuit CNT, a pad PAD and a power supply BIAS. The transistor T24 is, for example, a P-type transistor. The transistors T25 and T26 are, for example, N-type transistors.

The transistor T24 has a first end to which the voltage VRD is applied, a second end connected to the interconnect PBUSBS, and a gate connected to the node PBUSBS_PREn. The transistor T25 has a first end connected to the interconnect PBUSBS, a second end to be grounded, and a gate connected to the node PBUSBS_RST. The transistor T26 has a first end connected to the interconnect PBUSBS, a second end connected to the pad PAD, and a gate connected to a node MON_EN.

The control circuit CNT has an input end connected to the interconnect PBUSBS. The control circuit CNT has a function of determining whether or not the interconnect BLKSELn is disconnected based on the voltage of the interconnect PBUSBS. Note that the control circuit CNT is a circuit used in first and second examples of a disconnection detection operation to be described later. Thus, the control circuit CNT need not be provided if a third example of the disconnection detection operation to be described later is applied.

The pad PAD has an output end configured to be connectable with an external device of the memory device 3. The pad PAD is connected to the interconnect PBUSBS through the transistor T26 to supply information to the external device of the memory device 3 to determine whether the interconnect BLKSELn is disconnected. Note that the pad PAD and the transistor T26 are circuits for use in the third example of the disconnection detection operation to be described later. Thus, the pad PAD or the transistor T26 need not be provided if the third example to be described later is not applied.

The power supply BIAS has an input end to be grounded and an output end connected to the interconnect BSNOD_SUP. The power supply BIAS is configured to apply to the interconnect BSNOD_SUP, for example, an optional voltage that is equal to or higher than the voltage VSS and equal to or lower than the voltage VRD.

### 1. 1. 4. 3 Planar Layout

Next is a description of a planar layout of the row decoder RD.

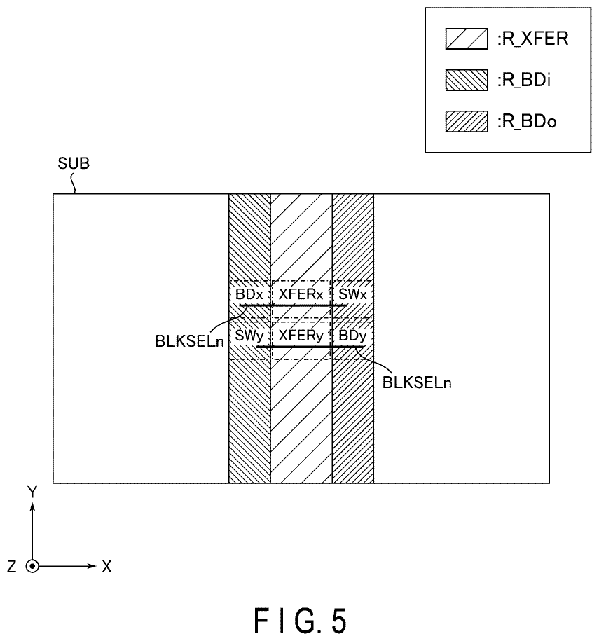

FIG. 5 is a plan view showing an example of a planar layout of a row decoder according to the first embodiment. FIG. 5 shows an example of a planar layout of the row decoder RD in a substrate SUB constituting the memory device 3. Hereinafter, a plane parallel to the surface of the substrate SUB will be defined as an XY plane. In the XY plane, the direction in which the word line WL extends will be defined as an X direction. In the XY plane, the direction in which the bit line BL extends will be defined as a Y direction. The direction that intersects the surface of the substrate SUB will be defined as a Z direction.

As shown in FIG. 5, the substrate SUB includes regions R_XFER, R_BDi and R_BDo. The row decoder RD is configured by these regions.

In the region R_XFER, the transfer switch XFER of the row decoder RD is provided. The region R_XFER is located in the central part of the substrate SUB in the X direction and extends in the Y direction.

In the regions R_BDi and R_BDo, the block decoder BD and disconnection detection switch SW of the row decoder RD are provided. The regions R_BDi and R_BDo sandwich the region R_XFER in the X direction and are each in contact with the region R_XFER.

In the regions R_BDi and R_BDo, the block decoder BD and the disconnection detection switch SW are aligned with their corresponding transfer switch XFER in the X direction.

In the example of FIG. 5, in the region R_Bdi, a block decoder BDx corresponding to a block BLKx may be aligned with a transfer switch XFERx corresponding to the block BLKx in the X direction. In this case, in the region R_BDo, a disconnection detection switch SWx corresponding to the block BLKx is aligned with the transfer switch XFERx corresponding to the block BLKx in the X direction.

In the region R_BDo, a block decoder BDy corresponding to a block BLKy different from the block BLKx can be aligned with a transfer switch XFERy corresponding to the block BLKy in the X direction. In this case, in the region R_Bdi, a disconnection detection switch SWy corresponding to the block BLKy is aligned with the transfer switch XFERy corresponding to the block BLKy in the X direction.

As described above, the block decoder BD and disconnection detection switch SW corresponding to the same block BLK are arranged so as to sandwich their corresponding transfer switch XFER in the X direction. A portion of the interconnect BLKSELn which connects the block decoder BD and the disconnection detection switch SW (referred to as a “main portion” hereinafter) extends in the X direction from the block decoder BD across the transfer switch XFER and reaches the disconnection detection switch SW. In the planar layout described above, the main portion of the interconnect BLKSELn has a length of, for example, several 100 μm or more in proportion to the number of transistors TR in the transfer switch XFER.

### 1. 2 Operation

Next is a description of a disconnection detection operation in the memory device according to the first embodiment.

The disconnection detection operation is an operation of determining whether or not a voltage supplied from the power supply BIAS to the interconnect BSNOD_SUP is transferred to the interconnect PBUSBS via the interconnect BLKSELn to detect a disconnection of the interconnect BLKSELn.

Three different disconnection detection operations in the memory device 3 will be described. Hereinafter, the components (block BLK, interconnect, etc.) of disconnection detection targets will be called “target components.”

### 1. 2. 1 First Example

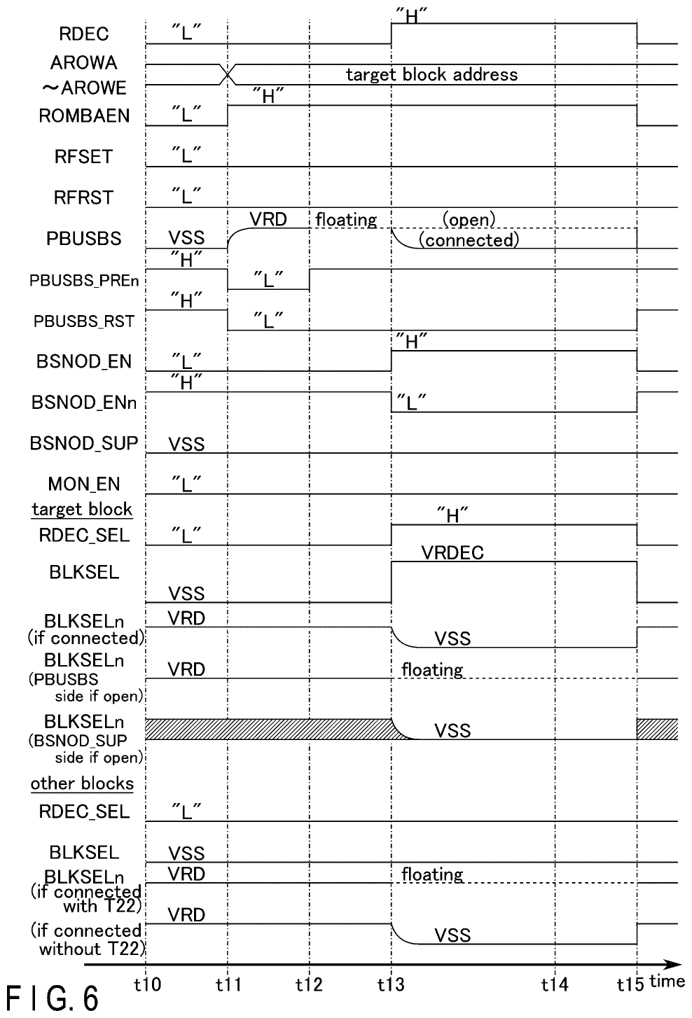

FIG. 6 is a timing chart showing a first example of a disconnection detection operation in the memory device according to the first embodiment. The first example corresponds to a case where a voltage VSS is applied from the power supply BIAS to the interconnect BSNOD_SUP.

At time t10, the row decoder module 15 is in a standby state to supply the nodes AROWA, AROWB, AROWC, AROWD and AROWE with a block address corresponding to the block BLK that was accessed immediately before the supply of the block address and also supply the nodes RDEC, ROMBAEN, RFSET, RFRST and BSNOD_EN with an “L” level signal. Accordingly, the voltage VSS is applied to the nodes RDEC_SEL of all of the blocks BLK. Thus, the voltage VSS is applied to the interconnects BLKSEL of all of the blocks BLK. In addition, the voltage VRD is applied to the interconnects BLKSELn of all of the blocks BLK. Note that if the interconnect BLKSELn is disconnected, the voltage VRD is applied to the interconnect BLKSELn alongside the interconnect PBUSBS from the place of the disconnection. On the other hand, the interconnect BLKSELn located alongside the interconnect BSNOD_SUP from the place of the disconnection is in an indeterminate state.

The row decoder module 15 also supplies the nodes PBUSBS_PREn and PBUSBS_RST with an “H” level signal and supplies the node MON_EN with an “L” level signal. Accordingly, the voltage VSS is applied to the interconnect PBUSBS.

In addition, the row decoder module 15 sets the power supply BIAS to the voltage VSS. Accordingly, the voltage VSS is applied to the interconnect BSNOD_SUP.

At time t11, the row decoder module 15 supplies the nodes AROWA, AROWB, AROWC, AROWD and AROWE with a signal indicating a block address corresponding to a target block BLK (target block address in FIG. 6). The row decoder module 15 supplies the node ROMBAEN with an “H” level signal. Accordingly, the node RDEC_SEL of a non-target block BLK is maintained at an “L” level. On the other hand, the node RDEC_SEL of the target block BLK is capable of shifting to the “H” level, regardless of whether the state of the target block BLK is in a good state or a bad state. Note that at time t1l, the node RDEC is maintained at the “L” level and thus the node RDEC_SEL of the target block BLK is also maintained at the “L” level.

The row decoder module 15 supplies the nodes PBUSBS_PREn and PBUSBS_RST with an “L” level signal. Accordingly, the voltage VRD is applied to the interconnect PBUSBS.

At time t12, the row decoder module 15 supplies the node PBUSBS_PREn with an “H” level signal. Accordingly, the interconnect PBUSBS is brought into a floating state.

At time t13, row decoder module 15 supplies the nodes BSNOD_EN and RDEC with an “H” level signal. Accordingly, the voltage VRD is applied to the node RDEC_SEL of the target block BLK. Thus, the voltage (e.g., voltage VRD) of the node VRDEC is applied to the interconnect BLKSEL of the target block BLK. In addition, the interconnect BLKSELn of the target block BLK is connected to the interconnects PBUSBS and BSNOD_SUP. Note that the nodes RDEC_SEL of the non-target blocks BLK (the other blocks in FIG. 6) are maintained at the voltage VSS. Accordingly, the interconnects BLKSEL of the non-target blocks BLK are maintained at the voltage VSS. If the transistor T22 is present, the interconnects BLKSELn of the non-target blocks BLK are brought into a floating state because the transistor T17 is turned off while being disconnected from the interconnect BSNOD_SUP. If the transistor T22 is not present, the interconnects BLKSELn are connected to the interconnect BSNOD_SUP.

If the interconnect BLKSELn of the target block BLK is not disconnected, the voltage of the interconnect BLKSELn lowers from the voltage VRD to the voltage VSS. The interconnect PBUSBS transitions from the floating state to a state in which it is connected to the interconnect BSNOD_SUP via the interconnect BLKSELn of the target block BLK. Therefore, the voltage of the interconnect PBUSBS lowers to the voltage VSS. The interconnects BLKSELn of the non-target blocks BLK are brought into a floating state if the transistor T22 is present, and lowers to the voltage VSS if the transistor T22 is not present.

If the interconnect BLKSELn of the target block BLK is disconnected, the voltage of a portion of the interconnect BLKSELn of the target block BLK, which is located alongside the interconnect BSNOD_SUP from the place of the disconnection, lowers to the voltage VSS, while a portion thereof which is located alongside the interconnect PBUSBS from the place of the disconnection is brought into a floating state. Thus, the interconnect PBUSBS is maintained in a floating state.

At time t14, the control circuit CNT of the row decoder module 15 determines whether the voltage VSS is applied to the interconnect PBUSBS. If the voltage VSS is not applied to the interconnect PBUSBS (that is, the interconnect PBUSBS is in a floating state), the control circuit CNT determines that the interconnect BLKSELn of the target block BLK is disconnected. If the voltage VSS is applied to the interconnect PBUSBS, the control circuit CNT determines that the interconnect BLKSELn of the target block BLK is not disconnected.

At time t15, the row decoder module 15 supplies an “L” level signal to the nodes RDEC, ROMBAEN and BSNOD_EN. The row decoder module 15 supplies an “H” level signal to the node PBUSBS_RST. Thus, the disconnection detection operation for the target block BLK is completed.

The above-described operations at time t10 to time t15 are performed in sequence for all of the blocks BLK. Accordingly, the disconnection detection operation for all of the blocks BLK is completed.

### 1. 2. 2 Second Example

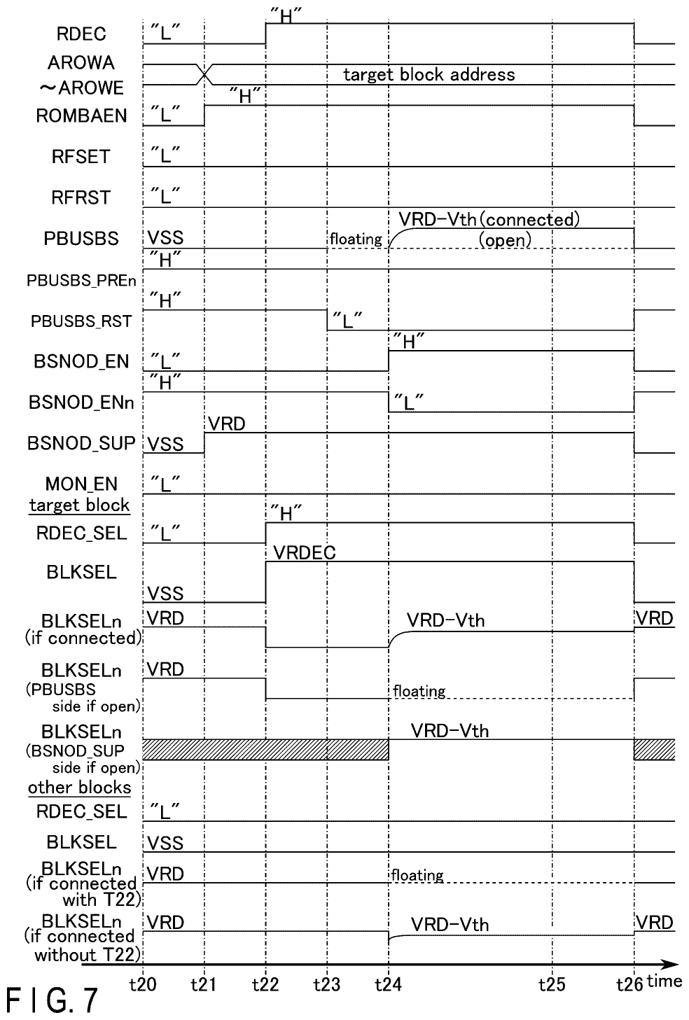

FIG. 7 is a timing chart showing a second example of the disconnection detection operation in the memory device according to the first embodiment. The second example corresponds to a case where the voltage VRD is applied from the power supply BIAS to the interconnect BSNOD_SUP.

At time t20, the row decoder module 15 is in a standby state to supply the nodes AROWA, AROWB, AROWC, AROWD and AROWE with a block address corresponding to the block BLK that was accessed immediately before the supply of the block address and also supply the nodes RDEC, ROMBAEN, RFSET, RFRST and BSNOD_EN with an “L” level signal. Accordingly, the voltage VSS is applied to the nodes RDEC_SEL of all of the blocks BLK. Thus, the voltage VSS is applied to the interconnects BLKSEL of all of the blocks BLK. In addition, the voltage VRD is applied to the interconnects BLKSELn of all of the blocks BLK. Note that if the interconnect BLKSELn is disconnected, the voltage VRD is applied to the interconnect BLKSELn located alongside the interconnect PBUSBS from the place of the disconnection. On the other hand, the interconnect BLKSELn located alongside the interconnect BSNOD_SUP from the place of the disconnection is in an indeterminate state.

In addition, the row decoder module 15 supplies the nodes PBUSBS_PREn and PBUSBS_RST with an “H” level signal. The row decoder module 15 also supplies the node MON_EN with an “L” level signal. Accordingly, the voltage VSS is applied to the interconnect PBUSBS.

In addition, the row decoder module 15 sets the power supply BIAS to the voltage VSS. Accordingly, the voltage VSS is applied to the interconnect BSNOD_SUP.

At time t21, the row decoder module 15 supplies the nodes AROWA, AROWB, AROWC, AROWD and AROWE with a signal indicating a block address corresponding to a target block BLK (target block address in FIG. 7). The row decoder module 15 supplies the node ROMBAEN with an “H” level signal. Accordingly, the node RDEC_SEL of a non-target block BLK is maintained at an “L” level. On the other hand, the node RDEC_SEL of the target block BLK is capable of shifting to the “H” level, regardless of whether the state of the target block BLK is in a good state or a bad state. Note that at time t21, the node RDEC is maintained at the “L” level and thus the node RDEC_SEL of the target block BLK is also maintained at the “L” level.

The row decoder module 15 sets the power supply BIAS to the voltage VRD. Accordingly, the voltage VRD is applied to the interconnect BSNOD_SUP.

At time t22, the row decoder module 15 supplies the node RDEC with an “H” level signal. Accordingly, the voltage VRD is applied to the node RDEC_SEL of the target block BLK. Thus, the voltage (e.g., voltage VRD) of the node VRDEC is applied to the interconnect BLKSEL of the target block BLK. In addition, the voltage VSS is applied to the interconnect BLKSELn of the target block BLK via the transistor T20. That is, if the interconnect BLKSELn of the target block BLK is disconnected, the voltage of a portion of the interconnect BLKSELn of the target block BLK, which is located alongside the interconnect BSNOD_SUP from the place of the disconnection, lowers to the voltage VSS, while a portion thereof which is located alongside the interconnect PBUSBS from the place of the disconnection is maintained in an indeterminate state. Note that the node RDEC_SEL of the non-target block BLK (the other blocks in FIG. 7) is maintained at the voltage VSS. Thus, the interconnects BLKSEL and BLKSELn of the non-target block BLK are maintained at the voltages VSS and VRD, respectively.

At time t23, the row decoder module 15 supplies the node PBUSBS_RST with an “L” level signal. Accordingly, the interconnect PBUSBS is brought into a floating state.

At time t24, the row decoder module 15 supplies the node BSNOD_EN with an “H” level signal. The interconnect BLKSELn of the target block BLK is thus connected to the interconnects PBUSBS and BSNOD_SUP. If the transistor T22 is present, the interconnect BLKSELn of the non-target block BLK is brought into a floating state because the transistor T17 is turned off while being disconnected from the interconnect BSNOD_SUP. If the transistor T22 is not present, the interconnect BLKSELn is connected to the interconnect BSNOD_SUP.

If the interconnect BLKSELn of the target block BLK is not disconnected, the voltage of the interconnect BLKSELn of the target block BLK rises from the voltage VSS to the voltage (VRD−Vth). Here, the voltage Vth is a higher one of the threshold voltages of the transistors T23 and T22. The interconnect PBUSBS transitions from a floating state to a state in which it is connected to the interconnect BSNOD_SUP via the interconnect BLKSELn of the target block BLK. Thus, the voltage of the interconnect PBUSBS becomes an “H” level that is equal to or lower than the voltage (VRD−Vth). The interconnect BLKSELn of the non-target block BLK is brought into a floating state if the transistor T22 is present, and is brought into a voltage (VRD−Vth) if the transistor T22 is not present.

If the interconnect BLKSELn of the target block BLK is disconnected, the voltage of a portion of the interconnect BLKSELn of the target block BLK, which is located alongside the interconnect BSNOD_SUP from the place of the disconnection, rises to the voltage (VRD−Vth), while a portion thereof which is located alongside the interconnect PBUSBS from the place of the disconnection is brought into a floating state. Thus, the interconnect PBUSBS is maintained in a floating state.

At time t25, the control circuit CNT of the row decoder module 15 determines whether the interconnect PBUSBS is supplied with an “H” level signal that is equal to or lower than the voltage (VRD−Vth). If the interconnect PBUSBS is not supplied with the signal (that is, the interconnect PBUSBS is in a floating state), the control circuit CNT determines that the interconnect BLKSELn of the target block BLK is disconnected. If the interconnect PBUSBS is supplied with the signal, the control circuit CNT determines that the interconnect BLKSELn of the target block BLK is not disconnected.

At time t26, the row decoder module 15 supplies an “L” level signal to the nodes RDEC, ROMBAEN and BSNOD_EN. The row decoder module 15 supplies an “H” level signal to the node PBUSBS_RST. Thus, the disconnection detection operation for the target block BLK is completed.

The above-described operations at time t20 to time t26 are performed in sequence for all of the blocks BLK. Accordingly, the disconnection detection operation for all of the blocks BLK is completed.

### 1. 2. 3 Third Example

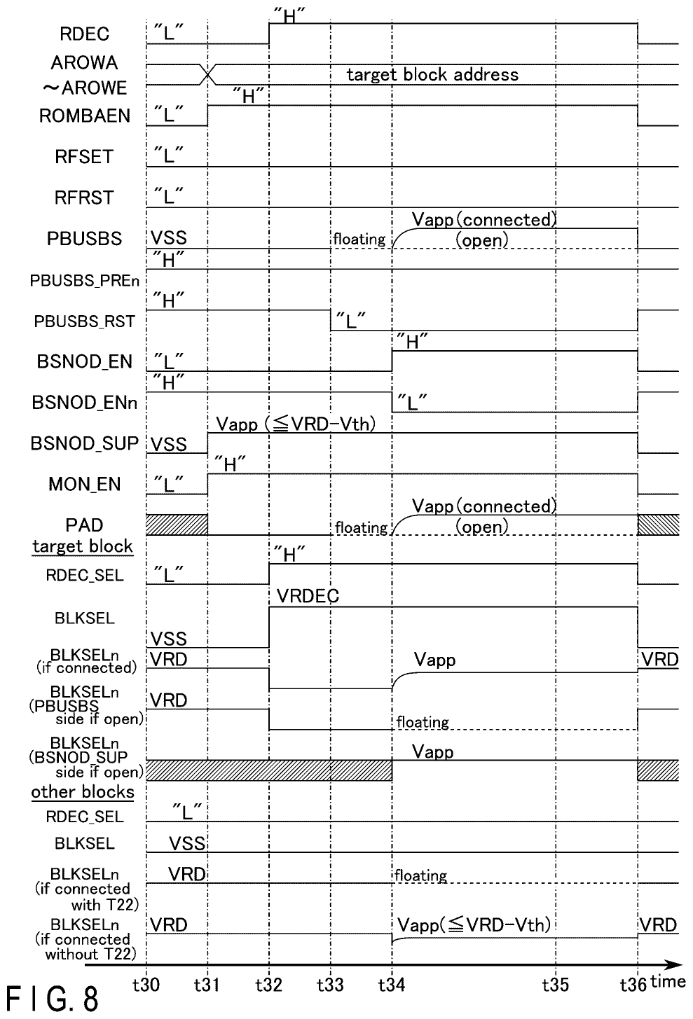

FIG. 8 is a timing chart showing a third example of the disconnection detection operation in the memory device according to the first embodiment. The third example corresponds to a case where a voltage Vapp, which is equal to or higher than the voltage VSS and equal to or lower than the voltage VRD−Vth, is applied from the power supply BIAS to the interconnect BSNOD_SUP, and a signal for detecting a disconnection is output to the pad PAD.

At time t30, the row decoder module 15 is in a standby state to supply the nodes AROWA, AROWB, AROWC, AROWD and AROWE with a block address corresponding to the block BLK that was accessed immediately before the supply of the block address and also supply the nodes RDEC, ROMBAEN, RFSET, RFRST and BSNOD_EN with an “L” level signal. Accordingly, the voltage VSS is applied to the nodes RDEC_SEL of all of the blocks BLK. Thus, the voltage VSS is applied to the interconnects BLKSEL of all of the blocks BLK. In addition, the voltage VRD is applied to the interconnects BLKSELn of all of the blocks BLK. Note that if the interconnect BLKSELn is disconnected, the voltage VRD is applied to the interconnect BLKSELn located alongside the interconnect PBUSBS from the place of the disconnection. On the other hand, the interconnect BLKSELn located alongside the interconnect BSNOD_SUP from the place of the disconnection is in an indeterminate state.

The row decoder module 15 also supplies the nodes PBUSBS_PREn and PBUSBS_RST with an “H” level signal. Accordingly, the voltage VSS is applied to the interconnect PBUSBS.

The row decoder module 15 also supplies the node MON_EN with an “L” level signal. Thus, the pad PAD is brought into an indeterminate state.

In addition, the row decoder module 15 sets the power supply BIAS to the voltage VSS. Accordingly, the voltage VSS is applied to the interconnect BSNOD_SUP.

At time t31, the row decoder module 15 supplies the nodes AROWA, AROWB, AROWC, AROWD and AROWE with a signal indicating a block address corresponding to a target block BLK (target block address in FIG. 8). The row decoder module 15 supplies the node ROMBAEN with an “H” level signal. Accordingly, the node RDEC_SEL of a non-target block BLK is maintained at an “L” level. On the other hand, the node RDEC_SEL of the target block BLK is capable of shifting to the “H” level, regardless of whether the state of the target block BLK is in a good state or a bad state. Note that at time t31, the node RDEC is maintained at the “L” level and thus the node RDEC_SEL of the target block BLK is also maintained at the “L” level.

The row decoder module 15 supplies the node MON_EN with an “H” level signal. Thus, the voltage VSS is applied to the pad PAD.

The row decoder module 15 sets the power supply BIAS to the voltage Vapp. Accordingly, the voltage Vapp is applied to the interconnect BSNOD_SUP.

At time t32, the row decoder module 15 supplies the node RDEC with an “H” level signal. Accordingly, the voltage VRD is applied to the node RDEC_SEL of the target block BLK. Thus, the voltage (e.g., voltage VRD) of the node VRDEC is applied to the interconnect BLKSEL of the target block BLK. In addition, the voltage VSS is applied to the interconnect BLKSELn of the target block BLK via the transistor T20. That is, if the interconnect BLKSELn of the target block BLK is disconnected, the voltage of a portion of the interconnect BLKSELn of the target block BLK, which is located alongside the interconnect BSNOD_SUP from the place of the disconnection, lowers to the voltage VSS, while a portion thereof which is located alongside the interconnect PBUSBS from the place of the disconnection is maintained in an indeterminate state. Note that the node RDEC_SEL of the non-target block BLK (the other blocks in FIG. 8) is maintained at the voltage VSS. Thus, the interconnects BLKSEL and BLKSELn of the non-target block BLK are maintained at the voltages VSS and VRD, respectively.

At time t33, the row decoder module 15 supplies the node PBUSBS_RST with an “L” level signal. Accordingly, the interconnects PBUSBS and pad PAD are brought into a floating state.

At time t34, the row decoder module 15 supplies the node BSNOD_EN with an “H” level signal. The interconnect BLKSELn of the target block BLK is thus connected to the interconnects PBUSBS and BSNOD_SUP. If the transistor T22 is present, the interconnect BLKSELn of the non-target block BLK is brought into a floating state because the transistor T17 is turned off while being disconnected from the interconnect BSNOD_SUP. If the transistor T22 is not present, the interconnect BLKSELn is connected to the interconnect BSNOD_SUP.

If the interconnect BLKSELn of the target block BLK is not disconnected, the voltage of the interconnect BLKSELn of the target block BLK rises from the voltage VSS to voltage Vapp (≤VRD−Vth). The interconnect PBUSBS and pad PAD transition from a floating state to a state in which they are connected to the interconnect BSNOD_SUP via the interconnect BLKSELn of the target block BLK. Thus, the voltages of the interconnect PBUSBS and pad PAD become an “H” level that is equal to or lower than the voltage Vapp. The interconnect BLKSELn of the non-target block BLK is brought into a floating state if the transistor T22 is present, and is brought into a voltage Vapp if the transistor T22 is not present.

If the interconnect BLKSELn of the target block BLK is disconnected, the voltage of a portion of the interconnect BLKSELn of the target block BLK, which is located alongside the interconnect BSNOD_SUP from the place of the disconnection, rises to the voltage Vapp, while a portion thereof which is located alongside the interconnect PBUSBS from the place of the disconnection is brought into a floating state. Therefore, unless a voltage or current is applied to the interconnect PBUSBS and the pad PAD particularly from an external device, they are maintained in a floating state at a VSS potential set at time t32 mainly due to the capacitance of interconnect from the interconnect PBUSBS to the pad PAD, the capacitance of interconnect and input from the pad PAD to the input end of the external device, and the capacitance of stabilization further added as necessary. At time t35, it is determined whether or not the pad PAD is supplied with an “H” level signal whose voltage is equal to or lower than Vapp. If it is not supplied (that is, the interconnect PBUSBS is in a floating state), it can be determined that the interconnect BLKSELn of the target block BLK is disconnected. If it is supplied, it can be determined that the interconnect BLKSELn is not disconnected.

As another embodiment, the resistance value of a disconnection portion can be measured if a current is measured by applying a voltage (or a voltage is measured by supplying a current) from an external device via the pad PAD. For example, during a period from time t35 to time t36 in FIG. 8, the external device of the memory device 3 performs a resistance measuring operation via the pad PAD to determine whether the interconnect BLKSELn is disconnected or not. In the resistance measuring operation, a set of voltage V and current I, that is, P=(V, I), in the pad PAD is measured at least twice.

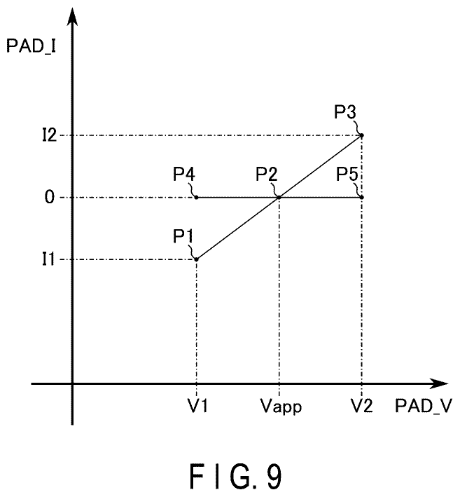

FIG. 9 is a graph showing an example of a resistance measuring operation in the memory device according to the first embodiment. In FIG. 9, measured values P1 to P5 are plotted on the graph when the horizontal axis indicates the voltage PAD V applied to the pad PAD and the vertical axis indicates the current PAD_I flowing through the pad PAD.

For example, when measured values P1=(V1, I1), P2=(Vapp, 0) and P3=(V2, I2) are measured via the pad PAD (V1<Vapp<V2, I1<0<I2), the external device of the memory device 3 calculates the resistance value R of the interconnect BLKSELn of the target block BLK as R=(V2−V1)/(I2−I1). If, in this way, the resistance value R is a significant value, the external device of the memory device 3 determines that the interconnect BLKSELn of the target block BLK is not disconnected.

On the other hand, when measured values P4=(V1, 0), P2=(Vapp, 0) and P5=(V2, 0) are measured via the pad PAD, the external device of the memory device 3 calculates the resistance value R of the interconnect BLKSELn of the target block BLK as ∞. If, in this way, the resistance value R is extraordinarily large, the external device of the memory device 3 determines that the interconnect BLKSELn of the target block BLK is disconnected.

At time t36, row decoder module 15 supplies an “L” level signal to the nodes RDEC, ROMBAEN, BSNOD_EN and MON_EN. The row decoder module 15 supplies an “H” level signal to the node PBUSBS_RST. If, therefore, the interconnect BLKSELn of the target block BLK is not disconnected, the voltage VRD is applied to the interconnect BLKSELn of the target block BLK. If the interconnect BLKSELn of the target block BLK is disconnected, a portion of the interconnect BLKSELn of the target block BLK, which is located alongside the interconnect BSNOD_SUP from the place of the disconnection, is brought into a floating state, and the voltage VRD is applied to a portion thereof located alongside the interconnect PBUSBS from the place of the disconnection. In addition, the pad PAD is brought into an indeterminate state. Thus, the disconnection detection operation for the target block BLK is completed.

The operations at time t30 to time t36 described above are performed in sequence for all of the blocks BLK. Accordingly, the disconnection detection operation for all of the blocks BLK is completed.

### 1. 3 Advantageous Effects of First Embodiment

According to the first embodiment, the interconnect BLKSELn has a first end connected to the gate of each of the transistors TR17 to TR25 of the transfer switch XFER, a second end connected to the transistors T18 and T19 of the block decoder BD, and a third end connected to the transistor T23 of the disconnection detection switch SW. The transistor T23 is connected to the power supply BIAS via the interconnect BSNOD_SUP. Thus, the power supply BIAS can apply a voltage to the interconnect BLKSELn via the transistor T23. Therefore, the control circuit CNT can determine whether the interconnect BLKSELn is disconnected or not based on the voltage of the interconnect PBUSBS.

In addition, if the interconnect BLKSELn is disconnected, for example, during a read operation, no “H” level signal is supplied through the interconnect BLKSELn to the transistors TR17 to TR25 in the transfer switch XFER corresponding to the non-selected block BLK. As a result, the selection gate lines SGD and SGS corresponding to the non-selected block BLK cannot be connected to their respective interconnects USGD and USGS, and the selection transistors ST1 and ST2 in the non-selected block BLK may be turned on. Accordingly, an unnecessary current flows through the bit line BL via the NAND string NS of the non-selected block BLK, which may cause a read error, for example. It is therefore preferable to detect a disconnection in the interconnect BLKSELn to obtain a defective chip.

According to the first embodiment, the main portion of the interconnect BLKSELn, which connects the block decoder BD and the disconnection detection switch SW, includes a portion that passes above the transfer switch XFER on the substrate SUB. Thus, in the disconnection detection operation, if the interconnect BLKSELn is not disconnected, the interconnect PBUSBS follows the voltage of the power supply BIAS, but if it is disconnected, the interconnect PBUSBS is brought into a floating state. Specifically, for example, in the first example of the disconnection detection operation in which the power supply BIAS supplies the voltage VSS, if the interconnect BLKSELn is not disconnected, the voltage of the interconnect PBUSBS lowers from VRD to VSS. For example, in the second example of the disconnection detection operation in which the power supply BIAS supplies the voltage VRD, if the interconnect BLKSELn is not disconnected, the voltage of the interconnect PBUSBS rises from VSS to (VRD−Vth). For example, in the third example of the disconnection detection operation in which the power supply BIAS supplies the voltage Vapp (≤VRD−Vth), if the interconnect BLKSELn is not disconnected, the voltage of the interconnect PBUSBS rises from VSS to Vapp. Thus, the control circuit CNT in the disconnection detection circuit ODC or the external device of the memory device 3 connected to the pad PAD can determine whether the interconnect BLKSELn is disconnected or not.

In addition, the block decoder BD is located in one of the regions R_BDi and R_BDo and its corresponding disconnection detection switch SW is located in the other region. Thus, the block decoder BD and the disconnection detection switch SW are located to sandwich the transfer switch XFER in the X direction and to be adjacent to the transfer switch XFER in the X direction. Therefore, the disconnection detection switch SW makes it possible to shorten the main portion of the interconnect BLKSELn by an additional portion thereof.

Even though the transistor T22 is not provided, the transistor T23 can control the connection between the interconnects BSNOD_SUP and BLKSELn. According to the embodiment, the disconnection detection switch SW includes the transistor T22 between the interconnect BLKSELn and the transistor T23. If, therefore, there is an interconnect BLKSELn having a large leak, the potential of the interconnect BSNOD_SUP can be prevented from fluctuating under the influence of the leak. The transistor T22 has a gate connected to the node RDEC_SEL. Thus, the voltage applied to the gate of the transistor T22 becomes the voltage VRD. Accordingly, the transistor T22 can be a low withstand voltage transistor to prevent the circuit area from increasing. On the other hand, if the transistor T22 is not provided, no interconnect corresponding to the transistor T22 and the node RDEC_SEL is required, thus preventing chip costs from increasing.

### 2. Second Embodiment

Next is a description of a second embodiment.

The second embodiment differs from the first embodiment in that the regions R_XFER and R_BD are respectively located at both ends of the substrate SUB in the X direction. Hereinafter, a configuration and an operation different from those of the first embodiment will be mainly described. A description of the configuration and operation equivalent to those of the first embodiment will be omitted as appropriate.

### 2. 1 Memory Cell Array

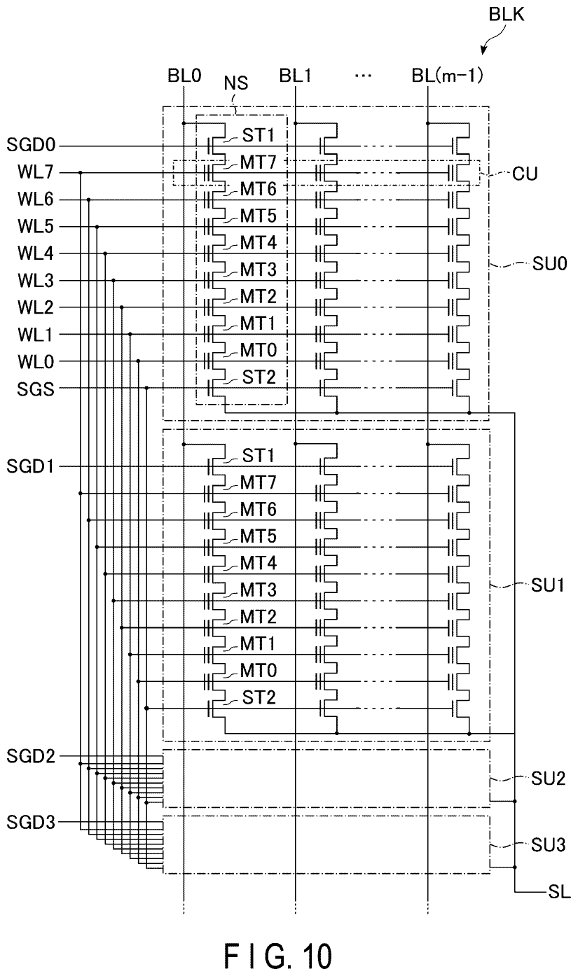

FIG. 10 is a circuit diagram showing an example of a circuit configuration of a memory cell array according to the second embodiment. FIG. 10 corresponds to FIG. 2 in the first embodiment.

As shown in FIG. 10, in the second embodiment, the gate of the selection transistor ST1 is connected to one selection gate line SGD in the same string unit SU. That is, the gates of the select transistors ST1 in the string units SU0 to SU3 are connected to their respective selection gate lines SGD0 to SGD3.

### 2. 2 Row Decoder Module

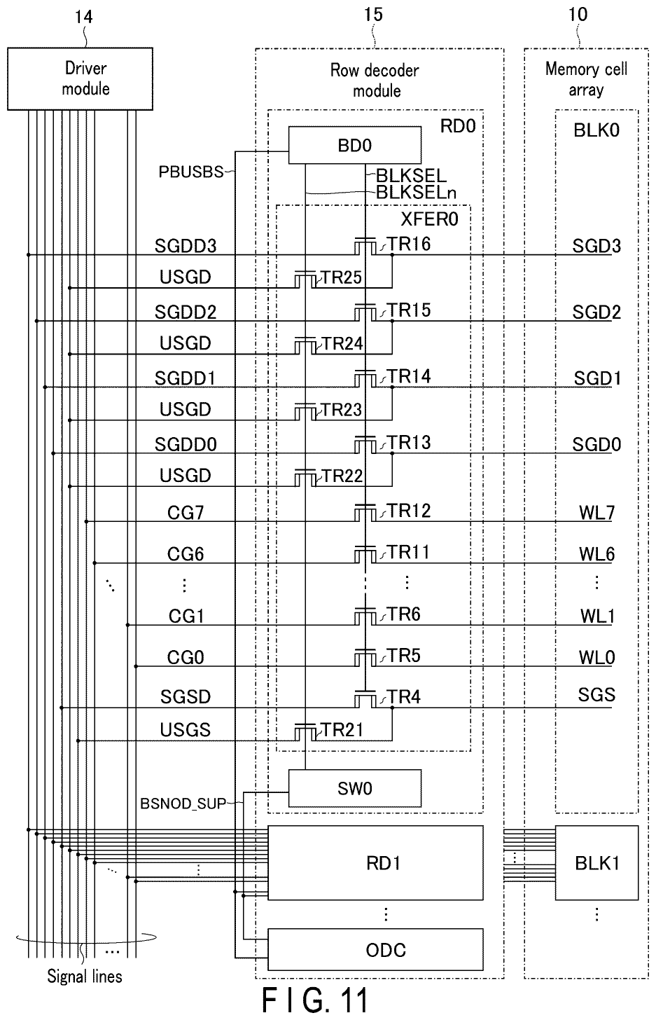

FIG. 11 is a circuit diagram showing an example of connection of a row decoder module according to the second embodiment and its peripheral circuits. FIG. 11 corresponds to FIG. 3 in the first embodiment.

As shown in FIG. 11, the row decoder module 15 includes a plurality of row decoders RD(RD0, RD1, . . . ) and a disconnection detection circuit ODC. The number of row decoders RD corresponds to the number of blocks BLK. In FIG. 11, an example of the configuration of the row decoder RD0 corresponding to the block BLK0 is shown. The row decoder RD0 includes a block decoder BD0, a transfer switch XFER0 and a disconnection detection switch SW0.

The row decoders RD have an equivalent configuration. The configuration of the row decoder RD corresponding to a certain block BLK will be described below with reference to FIG. 11.

The transfer switch XFER includes 18 transistors TR4 to TR16 and TR21 to TR25. These transistors are, for example, high withstand voltage N-type transistors.

The first end of each of the transistor TR4 is connected to its corresponding block BLK via a selection gate line SGS. The second end of the transistor TR4 is connected to the driver module 14 via its corresponding interconnect SGSD. The gate of the transistor TR4 is connected to its corresponding block decoder BD via the interconnect BLKSEL.

The first ends of the transistors TR5 to TR12 are connected to the blocks BLK via their respective word lines WL0 to WL7. The second ends of the transistors TR5 to TR12 are connected to the driver module 14 via their respective interconnects CG0 to CG7. The gate of each of the transistors TR5 to TR12 is connected to its corresponding block decoder BD via the interconnect BLKSEL.

The first ends of the transistors TR13, TR14, TR15 and TR16 are connected to their corresponding blocks BLK via their respective selection gate lines SGD0, SGD1, SGD2 and SGD3. The second ends of the transistors TR13, TR14, TR15 and TR16 are connected to the driver module 14 via their respective interconnects SGDD0, SGDD1, SGDD2 and SGDD3. The gate of each of the transistors TR13, TR14, TR15 and TR16 is connected to its corresponding block decoder BD via the interconnect BLKSEL.

The first end of the transistor TR21 is connected to is corresponding block BLK via the selection gate line SGS. The second end of the transistor TR21 is connected to the driver module 14 via the interconnect USGS. The gate of the transistor TR21 is connected to its corresponding block decoder BD and the disconnection detection switch SW via the interconnect BLKSELn.

The first ends of the transistors TR22, TR23, TR24 and TR25 are connected to their corresponding blocks BLK via their respective selection gate lines SGD0, SGD1, SGD2 and SGD3. The second ends of the transistors TR22, TR23, TR24 and TR25 are connected to the driver module 14 via the interconnect USGD. The gate of each of the transistors TR22, TR23, TR24 and TR25 is connected to its corresponding block decoder BD and disconnection detection switch SW via the interconnect BLKSELn.

The disconnection detection circuit ODC is connected to a plurality of block decoders BD corresponding to their respective blocks BLK via the interconnect PBUSBS. The disconnection detection circuit ODC is connected to a plurality of disconnection detection switches SW corresponding to their respective blocks BLK via the interconnect BSNOD_SUP. The configurations of the block decoder BD, disconnection detection switch SW and disconnection detection circuit ODC are the same as those of the first embodiment.

### 2. 3 Planar Layout

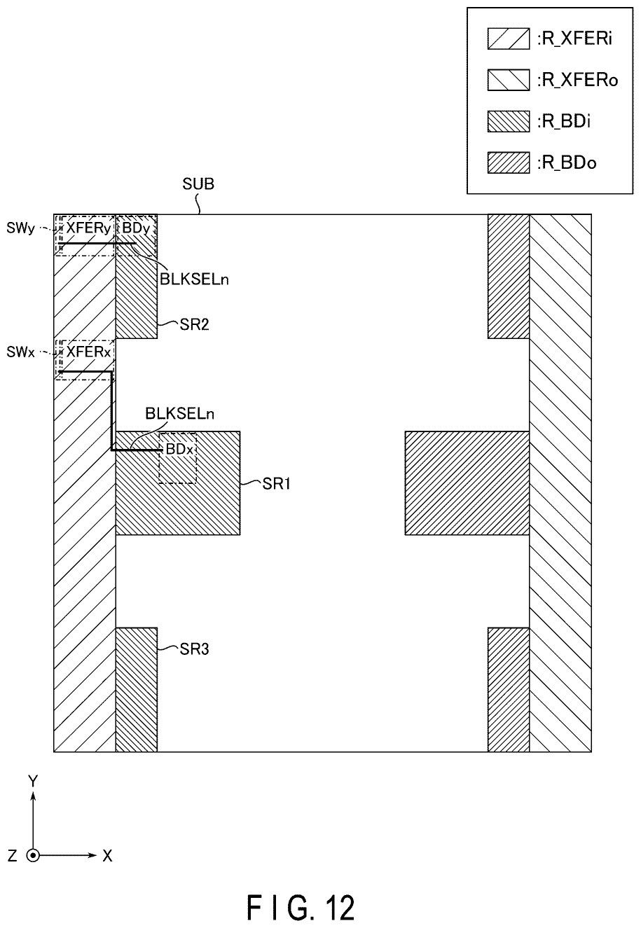

FIG. 12 is a plan view showing an example of a planar layout of a row decoder according to the second embodiment. FIG. 12 corresponds to FIG. 5 of the first embodiment.

As shown in FIG. 12, the substrate SUB includes regions R_XFERi, R_XFERo, R_BDi and R_BDo. The row decoder RD is configured by regions R_XFERi, R_XFERo, R_BDi and R_BDo.

The regions R_XFERi and R_XFERo are regions in the row decoder RD where the transfer switch XFER and the disconnection detection switch SW are provided. The regions R_XFERi and R_XFERo are located at their respective ends of the substrate SUB in the X direction and extend in the Y direction.

The regions R_BDi and R_BDo are regions in the row decoder RD where the block decoder BD is provided. The region R_BDi is in contact with the region R_XFERi. The region R_BDo is in contact with the region R_XFERo. Each of the regions R_BDi and R_BDo is divided into a plurality of partial regions SR which are separated from each other in the Y direction. In the example shown in FIG. 12, each of the regions R_BDi and R_BDo is divided into three portions of a partial region SR1 and two partial regions SR2 and SR3 which sandwich the partial region SR1 in the Y direction. The width of the partial region SR1 in the X direction is greater than that of each of the partial regions SR2 and SR3 in the X direction.

In the example of FIG. 12, the block decoder BDx corresponding to the block BLKx and the block decoder BDy corresponding to the block BLKy are located in their respective partial regions SR1 and SR2 of the region R_BDi.

The transfer switch XFERx and disconnection detection switch SWx corresponding to the block BLKx are aligned in the X direction, for example, in a region of the region R_XFERi which is located between the partial regions SR1 and SR2 of the region R_BDi. That is, the transfer switch XFERx and disconnection detection switch SWx are displaced from the block decoder BDx in the Y direction. The block decoder BDx and the block decoder BDy are displaced in the X direction. The block decoder BDx is further from the region R_XFERi than the block decoder BDy in the X direction. In this case, the main portion of the interconnect BLKSELn corresponding to the block BLKx extends in the X direction in the partial region SR1 between the block decoder BDx and the region R_XFERi. The main portion of the interconnect BLKSELn corresponding to the block BLKx extends between the block decoder BDx and the disconnection detection switch SWx so as to pass through the transfer switch XFERx without branching. Thus, the main portion of the interconnect BLKSELn corresponding to the block BLKx includes a portion extending in the Y direction and a portion extending in the X direction in the partial region SR1 between the block decoder BDx and the region R_XFERi.

On the other hand, the transfer switch XFERy and disconnection detection switch SWy corresponding to the block BLKy are located, for example, in a region of the region R_XFERi which is aligned with the partial region SR2 of the region R_BDi in the X direction. That is, the transfer switch XFERy and disconnection detection switch SWy are located at substantially the same position in the Y direction as the block decoder BDy. The block decoder BDy is adjacent to the transfer switch XFERy in the X direction. In this case, the main portion of the interconnect BLKSELn corresponding to the block BLKy extends between the block decoder BDy and the disconnection detection switch SWy so as to pass through the transfer switch XFERy without branching. Thus, the main portion of the interconnect BLKSELn corresponding to the block BLKy has neither a portion extending in the Y direction nor a portion extending in the X direction in the partial region SR2 between the block decoder BDy and the region R_XFERi. Note that it may have a portion extending in the X direction in the partial region SR2 between the block decoder BDy and the region R_XFERi. In this case, the portion extending in the X direction in the partial region SR2 between the block decoder BDy and the region R_XFERi is shorter than the portion extending in the X direction in the partial region SR2 between the block decoder BDx and the region R_XFERi.

As described above, the main portion of the interconnect BLKSELn corresponding to the block BLKx is longer than that of the interconnect BLKSELn corresponding to the block BLKy.

### 2. 4 Advantageous Effects of Second Embodiment

Since the block decoder BD is less limited in layout than other circuits such as the sense amplifier module 16, it may not always be located adjacent to its corresponding transfer switch XFER in the X direction. In this case, the block decoder BD and its corresponding transfer switch XFER may be provided apart from each other in the Y direction. In such a case, the interconnect BLKSELn is longer than that in the case where the block decoder BD and its corresponding transfer switch XFER are provided at substantially the same position in the Y direction; thus, the risk of disconnection of the interconnect BLKSELn may also increase.

According to the second embodiment, when the block decoder BD is located in the partial region SR1 of the region R_BDi, its corresponding disconnection detection switch SW and transfer switch XFER can be located apart from the partial region SR1 in the region R_XFERi in the Y direction. Since, therefore, the main portion of the interconnect BLKSELn further includes a relatively long portion such as a portion extending in the Y direction between the block decoder BD and the transfer switch XFER and a portion extending in the X direction in the partial region SR between the block decoder BD and the transfer switch XFER, the portion extending in the X direction between the transfer switch XFER and the disconnection detection switch SW is relatively short although the length of the interconnect is extended. Therefore, the addition of the main portion of the interconnect BLKSELn can be shortened by providing the disconnection detection switch SW.

### 3. Third Embodiment

Next is a description of a third embodiment.

The third embodiment differs from the first and second embodiments in that there are a plurality of blocks BLK corresponding to one block decoder BD. Hereinafter, the configuration and operation different from those of the second embodiment will be mainly described. A description of the configuration and operation equivalent to those of the second embodiment will be omitted as appropriate.

### 3. 1 Row Decoder Module

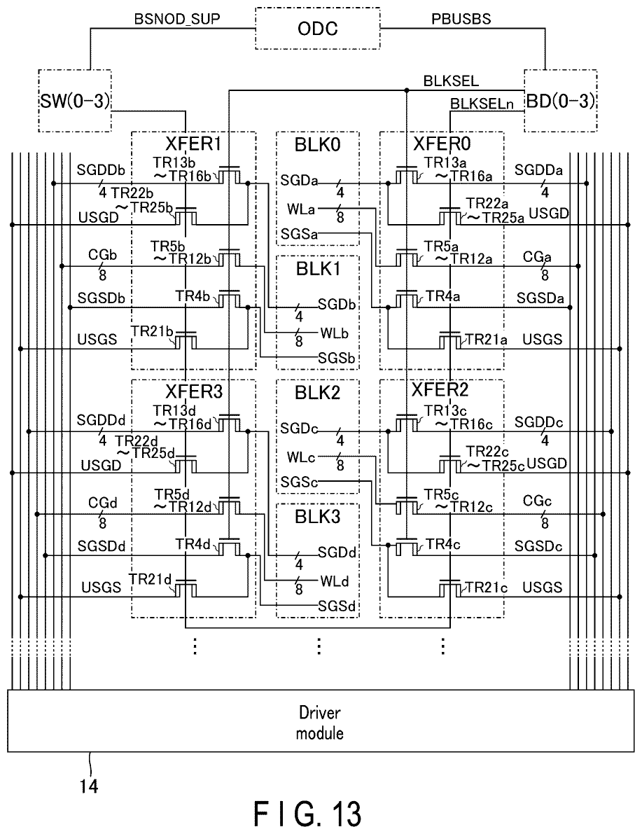

FIG. 13 is a circuit diagram showing an example of connection of a row decoder module according to the third embodiment and its peripheral circuits. FIG. 13 corresponds to FIG. 11 in the second embodiment.

As shown in FIG. 13, the row decoder module 15 includes a plurality of transfer switches XFER (XFER0, XFER1, XFER2, XFER3, . . . ), a plurality of block decoders BD (BD(0-3), . . . ), a plurality of disconnection detection switches SW (SW(0-3), . . . ), and a disconnection detection circuit ODC. The number of transfer switches XFER corresponds to the number of blocks BLK. The number of block decoders BD and the number of disconnection detection switches SW each correspond to ¼ of the number of blocks BLK. In FIG. 13, transfer switches XFER0, XFER1, XFER2 and XFER3 are shown to correspond to blocks BLK0, BLK1, BLK2 and BLK3, respectively as an example of the configuration. In addition, a block decoder BD (0-3) and a disconnection detection switch SW (0-3) are shown as a configuration common to the blocks BLK0, BLK1, BLK2 and BLK3.

The transfer switch XFER0 includes 18 transistors TR4a to TR16a and TR21a to TR25a. The transfer switch XFER1 includes 18 transistors TR4b to TR16b and TR21b to TR25b. The transfer switch XFER2 includes 18 transistors TR4c to TR16c and TR21c to TR25c. The transfer switch XFER3 includes 18 transistors TR4d to TR16d and TR21d to TR25d. The transistors TR4a to TR16a, TR4b to TR16b, TR4c to TR16c and TR4d to TR16d are high withstand voltage N-type transistors. The transistors TR21a to TR25a, TR21b to TR25b, TR21c to TR25c and TR21d to TR25d are also high withstand voltage N-type transistors.

First is a description of the configuration of the transfer switch XFER0.

The first end of the transistor TR4a is connected to the block BLK0 via the selection gate line SGSa. The second end of the transistor TR4a is connected to the driver module 14 via the interconnect SGSDa. The gate of the transistor TR4a is connected to the block decoder BD (0-3) via the interconnect BLKSEL.

The first ends of the transistors TR5a to TR12a are connected to the block BLK0 via their respective eight word lines WLa. The second ends of the transistors TR5a to TR12a are connected to the driver module 14 via their respective eight interconnects CGa. The gate of each of the transistors TR5a to TR12a is connected to its corresponding block decoder BD (0-3) via the interconnect BLKSEL.

The first ends of the transistors TR13a to TR16a are connected to the block BLK0 via their respective four selection gate lines SGDa. The second ends of the transistors TR13a to TR16a are connected to the driver module 14 via their respective four interconnects SGDDa. The gate of each of the transistors TR13a to TR16a is connected to its corresponding block decoder BD (0-3) via the interconnect BLKSEL.

The first end of the transistor TR21a is connected to the block BLK0 via the selection gate line SGSa. The second end of the transistor TR21a is connected to the driver module 14 via the interconnect USGS. The gate of the transistor TR21a is connected to the block decoder BD (0-3) and the disconnection detection switch SW (0-3) via the interconnect BLKSELn.

The first ends of the transistors TR22a to TR25a are connected to the block BLK0 via their respective four selection gate lines SGDa. The second end of each of the transistors TR22a to TR25a is connected to the driver module 14 via the interconnect USGD. The gate of each of the transistors TR22a to TR25a is connected to the block decoder BD (0-3) and the disconnection detection switch SW (0-3) via the interconnect BLKSELn.

Next is a description of the configuration of the transfer switch XFER1.

The first end of the transistor TR4b is connected to the block BLK1 via the selection gate line SGSb. The second end of the transistor TR4b is connected to the driver module 14 via the interconnect SGSDb. The gate of the transistor TR4b is connected to the block decoder BD (0-3) via the interconnect BLKSEL.

The first ends of the transistors TR5b to TR12b are connected to the block BLK1 via their respective eight word lines WLb. The second ends of the transistors TR5b to TR12b are connected to the driver module 14 via their respective eight interconnects CGb. The gate of each of the transistors TR5b to TR12b is connected to its corresponding block decoder BD (0-3) via the interconnect BLKSEL.

The first ends of the transistors TR13b to TR16b are connected to the block BLK1 via their respective four selection gate lines SGDb. The second ends of the transistors TR13b to TR16b are connected to the driver module 14 via their respective four interconnects SGDDb. The gate of each of the transistors TR13b to TR16b is connected to its corresponding block decoder BD (0-3) via the interconnect BLKSEL.

The first end of the transistor TR21b is connected to the block BLK1 via the selection gate line SGSb. The second end of the transistor TR21b is connected to the driver module 14 via the interconnect USGS. The gate of the transistor TR21b is connected to the block decoder BD (0-3) and the disconnection detection switch SW (0-3) via the interconnect BLKSELn.

The first ends of the transistors TR22b to TR25b are connected to the block BLK1 via their respective four selection gate lines SGDb. The second end of each of the transistors TR22b to TR25b is connected to the driver module 14 via the interconnect USGD. The gate of each of the transistors TR22b to TR25b is connected to the block decoder BD (0-3) and the disconnection detection switch SW (0-3) via the interconnect BLKSELn.

Next is a description of the configuration of the transfer switch XFER2.

The first end of the transistor TR4c is connected to the block BLK2 via the selection gate line SGSc. The second end of the transistor TR4c is connected to the driver module 14 via the interconnect SGSDc. The gate of the transistor TR4c is connected to the block decoder BD (0-3) via the interconnect BLKSEL.

The first ends of the transistors TR5c to TR12c are connected to the block BLK2 via their respective eight word lines WLc. The second ends of the transistors TR5c to TR12c are connected to the driver module 14 via their respective eight interconnects CGc. The gate of each of the transistors TR5c to TR12c is connected to its corresponding block decoder BD (0-3) via the interconnect BLKSEL.

The first ends of the transistors TR13c to TR16c are connected to the block BLK2 via their respective four selection gate lines SGDc. The second ends of the transistors TR13c to TR16c are connected to the driver module 14 via their respective four interconnects SGDDc. The gate of each of the transistors TR13c to TR16c is connected to its corresponding block decoder BD (0-3) via the interconnect BLKSEL.

The first end of the transistor TR21c is connected to the block BLK2 via the selection gate line SGSc. The second end of the transistor TR21c is connected to the driver module 14 via the interconnect USGS. The gate of the transistor TR21c is connected to the block decoder BD (0-3) and the disconnection detection switch SW (0-3) via the interconnect BLKSELn.

The first ends of the transistors TR22c to TR25c are connected to the block BLK2 via their respective four selection gate lines SGDc. The second ends of the transistors TR22c to TR25c are connected to the driver module 14 via the interconnect USGD. The gate of each of the transistors TR22c to TR25c is connected to the block decoder BD (0-3) and the disconnection detection switch SW (0-3) via the interconnect BLKSELn.

Next is a description of the configuration of the transfer switch XFER3.

The first end of the transistor TR4d is connected to the block BLK3 via the selection gate line SGSd. The second end of the transistor TR4d is connected to the driver module 14 via the interconnect SGSDd. The gate of the transistor TR4d is connected to the block decoder BD (0-3) via the interconnect BLKSEL.

The first ends of the transistors TR5d to TR12d are connected to the block BLK3 via their respective eight word lines WLd. The second ends of the transistors TR5d to TR12d are connected to the driver module 14 via their respective eight interconnects CGd. The gate of each of the transistors TR5d to TR12d is connected to its corresponding block decoder BD (0-3) via the interconnect BLKSEL.

The first ends of the transistors TR13d to TR16d are connected to the block BLK3 via their respective four selection gate lines SGDd. The second ends of the transistors TR13d to TR16d are connected to the driver module 14 via their respective four interconnects SGDDd. The gate of each of the transistors TR13d to TR16d is connected to its corresponding block decoder BD (0-3) via the interconnect BLKSEL.

The first end of the transistor TR21d is connected to the block BLK3 via the selection gate line SGSd. The second end of the transistor TR21d is connected to the driver module 14 via the interconnect USGS. The gate of the transistor TR21d is connected to the block decoder BD (0-3) and the disconnection detection switch SW (0-3) via the interconnect BLKSELn.

The first ends of the transistors TR22d to TR25d are connected to the block BLK3 via their respective four selection gate lines SGDd. The second end of each of the transistors TR22d to TR25d is connected to the driver module 14 via the interconnect USGD. The gate of each of the transistors TR22d to TR25d is connected to the block decoder BD (0-3) and the disconnection detection switch SW (0-3) via the interconnect BLKSELn.

The disconnection detection circuit ODC is connected to a plurality of block decoders BD including a block decoder BD (0-3) via the interconnect PBUSBS. The disconnection detection circuit ODC is connected to a plurality of disconnection detection switches SW including a disconnection detection switch SW (0-3) via the interconnect BSNOD_SUP. The configurations of the block decoder BD (0-3), disconnection detection switch SW (0-3) and disconnection detection circuit ODC are the same as those of the block decoder BD, disconnection detection switch SW and disconnection detection circuit ODC in the second embodiment.

### 3. 2 Planar Layout

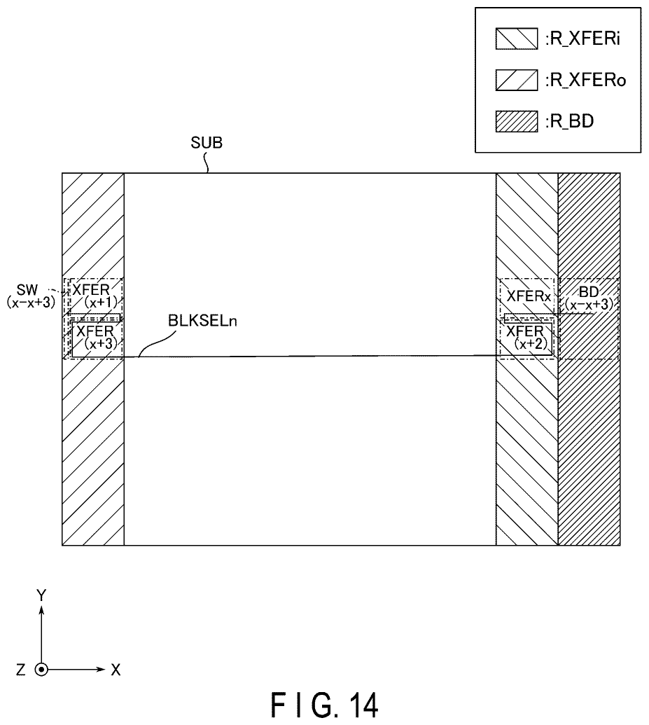

FIG. 14 is a plan view showing an example of a planar layout of the row decoder according to the third embodiment. FIG. 14 corresponds to FIG. 12 of the second embodiment.

As shown in FIG. 14, the substrate SUB includes regions R_XFERi, R_XFERo and R_BD.

The region R_BD is a region in which the block decoder BD is provided. The region R_BD is located at one end of the substrate SUB in the X direction, and extends in the Y direction. In the example of FIG. 14, a block decoder BD (x−x+3) corresponding to the blocks BLKx, BLK(x+1), BLK(x+2) and BLK(x+3) is located in the region R_BD.

The regions R_XFERi and R_XFERo are regions in which a transfer switch XFER and a disconnection detection switch SW are provided. The region R_XFERo is located at the other end of the substrate SUB in the X direction where the region R_BD is not provided, and extends in the Y direction. The region R_XFERi is in contact with the region R_BD and extends in the Y direction.

The transfer switches XFERx and XFER(x+2) are aligned in the Y direction in a region of the region R_XFERi that is in contact with the block decoder BD(x−x+3). The transfer switches XFER(x+1) and XFER(x+3) are aligned in the Y direction in a region of the region R_XFERo that is aligned in the X direction with the block decoder BD(x−x+3).

The disconnection detection switch SW(x−x+3) is located in a region of the region R_XFERo that is aligned with the transfer switches XFER(x+1) and XFER(x+3) in the X direction. The disconnection detection switch SW(x−x+3) and the block decoder BD(x−x+3) are arranged so as to sandwich the transfer switches XFERx, XFER(x+1), XFER(x+2) and XFER(x+3) in the X direction.

In the above case, the main portion of the interconnect BLKSELn common to the blocks BLKx, BLK(x+1), BLK(x+2) and BLK(x+3) extends between the block decoder BD(x−x+3) and the disconnection detection switch SW(x−x+3) so as to pass through the transfer switches XFERx, XFER(x+1), XFER(x+2) and XFER(x+3) without branching. That is, the main portion of the interconnect BLKSELn passes in sequence from the block decoder BD(x−x+3) through the transfer switches XFERx and XFER(x+2) in the region R_XFERi, passes through the transfer switches XFER(x+3) and XFER(x+1) in sequence in the region R_XFERo, and reaches the disconnection detection switch SW(x−x+3) in the region R_XFERo. Thus, the main portion of the interconnect BLKSELn has a portion extending in the X direction between the regions R_XFERi and R_XFERo. In the foregoing planar layout, the main portion of the interconnect BLKSELn has a length of about several thousand μm in order to sandwich a region having the memory cell array 10 between the regions R_XFERo and R_XFERi.

### 3. 3 Advantageous Effects of Third Embodiment

According to the third embodiment, one block decoder BD and one disconnection detection switch SW control four transfer switches XFER collectively. In this configuration, the main portion (that is, a portion connecting the block decoder BD and the disconnection detection switch SW) of the interconnect BLKSELn includes a portion on the substrate SUB which extends in the X direction so as to pass above each of the four transfer switches XFER. Thus, the control circuit CNT can detect a disconnection in the interconnect BLKSELn even though the disconnection occurs above any transfer switch XFER.

In addition, when the above main portion of the interconnect BLKSELn does not include a portion passing above at least one of the four transfer switches XFER (that is, if the interconnect BLKSELn is branched), the interconnect BSNOD_SUP is connected to the interconnect PBUSBS via the main portion of the interconnect BLKSELn even if a disconnection occurs in a portion not included in the main portion. Therefore, the control circuit CNT cannot detect a disconnection of a portion not included in the main portion.

According to the third embodiment, all of the portions that pass above the transfer switches XFER corresponding to the same block decoder BD are included in the main portion of the interconnect BLKSELn. Therefore, the control circuit CNT can detect a disconnection in the interconnect BLKSELn even though the disconnection occurs above any transfer switch XFER.

### 4. Fourth Embodiment

Next is a description of a fourth embodiment.

The fourth embodiment differs from the third embodiment in that the block decoder BD is located at either end of the substrate SUB in the X direction. Hereinafter, the configuration and operation different from those of the third embodiment will be mainly described. A description of the configuration and operation equivalent to those of the third embodiment will be omitted as appropriate.

### 4. 1 Row Decoder Module

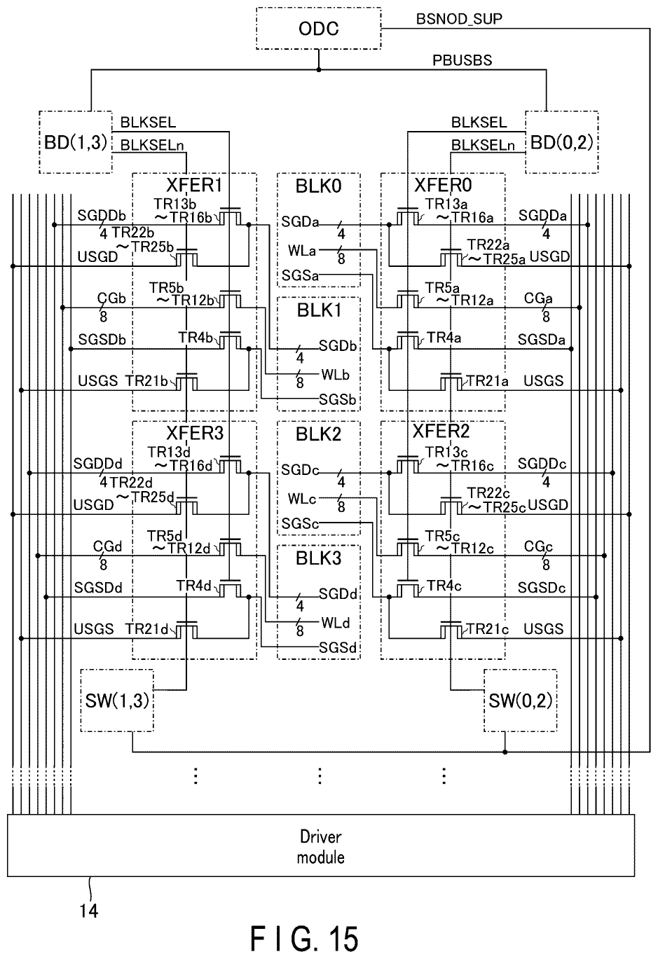

FIG. 15 is a circuit diagram showing an example of connection of a row decoder module according to the fourth embodiment and its peripheral circuits. FIG. 15 corresponds to FIG. 13 in the third embodiment.

As shown in FIG. 15, the row decoder module 15 includes a plurality of transfer switches XFER (XFER0, XFER1, XFER2, XFER3, . . . ), a plurality of block decoders BD (BD(0,2), BD(1,3), . . . ), a plurality of disconnection detection switches SW (SW (0,2), SW (1,3), . . . ), and a disconnection detection circuit ODC. The number of transfer switches XFER corresponds to the number of blocks BLK. The number of block decoders BD and the number of disconnection detection switches SW each correspond to ½ of the number of blocks BLK. In the example of FIG. 15, transfer switches XFER0, XFER1, XFER2 and XFER3 are configured to correspond to blocks BLK0, BLK1, BLK2 and BLK3, respectively. In addition, a block decoder BD(0,2) and a disconnection detection switch SW(0,2) are each common to the blocks BLK0 and BLK2, and a block decoder BD(1,3) and a disconnection detection switch SW(1,3) are each common to the blocks BLK1 and BLK3.

The connection between the transfer switches XFER0 to XFER3 and the blocks BLK0 to BLK3 and driver module 14 is the same as that in the third embodiment.

The gates of the transistors TR4a to TR16a are connected to their corresponding block decoder BD(0,2) via the interconnect BLKSEL corresponding to blocks BLK0 and BLK2. The gates of the transistors TR21a to TR25a are connected to the block decoder BD(0,2) and the disconnection detection switch SW(0,2) via the interconnect BLKSELn corresponding to the blocks BLK0 and BLK2.

The gates of the transistors TR4b to TR16b are connected to their corresponding block decoder BD(1,3) via the interconnect BLKSEL corresponding to the blocks BLK1 and BLK3. The gates of the transistors TR21b to TR25b are connected to the block decoder BD(1,3) and the disconnection detection switch SW(1,3) via the interconnect BLKSELn corresponding to the blocks BLK1 and BLK3.

The gates of the transistors TR4c to TR16c are connected to their corresponding block decoders BD(0,2) via the interconnect BLKSEL corresponding to the blocks BLK0 and BLK2. The gates of the transistors TR21c to TR25c are connected to the block decoder BD(0,2) and the disconnection detection switch SW(0,2) via the interconnect BLKSELn corresponding to the blocks BLK0 and BLK2.

The gates of the transistors TR4d to TR16d are connected to their corresponding block decoder BD(1,3) via the interconnect BLKSEL corresponding to the blocks BLK1 and BLK3. The gates of the transistors TR21d to TR25d are connected to the block decoder BD(1,3) and the disconnection detection switch SW(1,3) via the interconnect BLKSELn corresponding to the blocks BLK1 and BLK3.

The disconnection detection circuit ODC is connected to a plurality of block decoders BD including block decoders BD(0,2) and BD(1,3) via the interconnect PBUSBS. The disconnection detection circuit ODC is connected to a plurality of disconnection detection switches SW including disconnection detection switches SW(0,2) and SW(1,3) via the interconnect BSNOD_SUP. The configuration of the block decoders BD(0,2) and BD(1,3) is the same as that of the block decoder BD(0-3) in the third embodiment. The configuration of the disconnection detection switches SW(0,2) and SW(1,3) is the same as that of the disconnection detection switch SW(0-3) in the third embodiment.

### 4. 2 Planar Layout

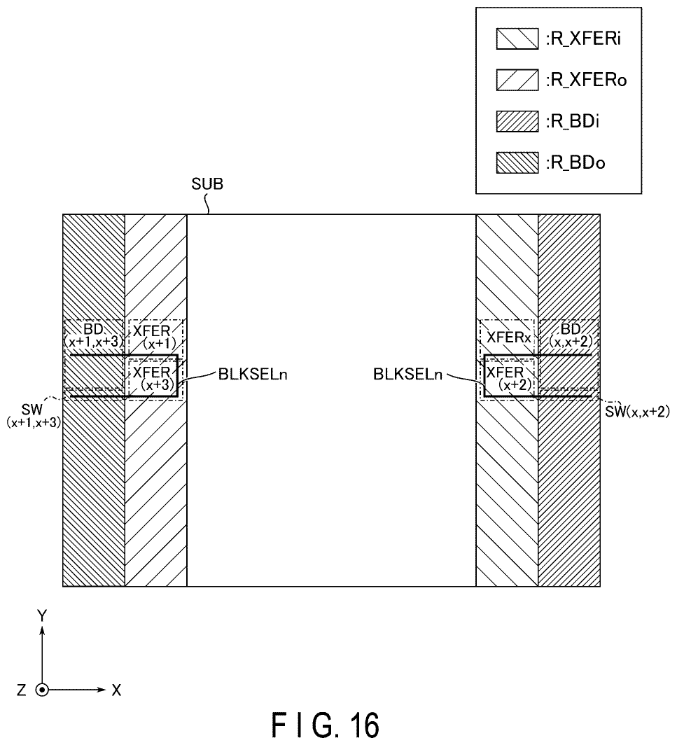

FIG. 16 is a plan view showing an example of a planar layout of the row decoder according to the fourth embodiment. FIG. 16 corresponds to FIG. 14 in the third embodiment.

As shown in FIG. 16, the substrate SUB includes regions R_XFERi, R_XFERo, R_BDi and R_BDo.

The regions R_BDi and R_BDo are provided with a block decoder BD and a disconnection detection switch SW. The regions R_BDi and R_BDo are located at both ends of the substrate SUB in the X direction and extend in the Y direction. In the example of FIG. 16, the block decoder BD(x, x+2) and disconnection detection switch SW(x, x+2) corresponding to the blocks BLKx and BLK(x+2) are aligned in the region R_BDi in the Y direction. The block decoders BD(x+1, x+3) and disconnection detection switches SW(x, x+2) corresponding to the blocks BLK(x+1) and BLK(x+3) are aligned in the region R_BDo in the Y direction.

The regions R_XFERi and R_XFERo are provided with the transfer switches XFER. The region R_XFERi is in contact with the region R_BDi and extends in the Y direction. The region R_XFERo is in contact with the region R_BDo and extends in the Y direction.

The transfer switches XFERx and XFER(x+2) are aligned in the Y direction in a region of the region R_XFERi, which is in contact with the block decoder BD(x, x+2) and the disconnection detection switch SW(x, x+2). The transfer switches XFER(x+1) and XFER(x+3) are aligned in the Y direction in a region of the region R_XFERo, which is in contact with the block decoder BD(x+1, x+3) and the disconnection detection switch SW(x+1, x+3).

In this case, the main portion of the interconnect BLKSELn common to the blocks BLKx and BLK(x+2) extends between the block decoder BD(x, x+2) and the disconnection detection switch SW(x, x+2) so as to pass through the transfer switches XFERx and XFER(x+2) without branching. That is, the main portion of the interconnect BLKSELn passes from the block decoder BD(x, x+2) in the region R_BDi to the disconnection detection switch SW(x, x+2) in the region R_BDi in order through the transfer switches XFERx and XFER (x+2) in the region R_XFERi. Therefore, the main portion of the interconnect BLKSELn has a portion extending so as to fold back in the X direction between the regions R_BDi and R_XFERi.

Similarly, the main portion of the interconnect BLKSELn common to the blocks BLK(x+1) and BLK(x+3) extends between the block decoder BD(x+1, x+3) and the disconnection detection switch SW(x+1, x+3) so as to pass through the transfer switches XFER(x+1) and XFER(x+3) without branching. That is, the main portion of the interconnect BLKSELn passes from the block decoder BD(x+1, x+3) in the region R_BDo to the disconnection detection switch SW(x+1, x+3) in the region R_BDo in order through the transfer switches XFER(x+1) and XFER(x+3) in the region R_XFERo. Therefore, the main portion of the interconnect BLKSELn has a portion extending so as to fold back in the X direction between the regions R_BDo and R_XFERo.

### 4. 3 Advantageous Effects of Fourth Embodiment

According to the fourth embodiment, one block decoder BD and one disconnection detection switch SW collectively control two transfer switches XFER arranged in the Y direction. The disconnection detection switch SW is located on the same side as the block decoder BD with respect to its corresponding two transfer switches XFER in the X direction. The main portion of the interconnect BLKSELn (that is, a portion connecting the block decoder BD and the disconnection detection switch SW) includes a portion on the substrate SUB extending in the X direction so as to pass above the corresponding two transfer switches XFER. That is, the main portion of the interconnect BLKSELn includes a portion passing above one of the two transfer switches XFER in the X direction and a portion passing above the other in the X direction, and these portions are aligned in the Y direction. In this configuration, as in the third embodiment, the control circuit CNT can detect a disconnection of the interconnect BLKSELn even though the disconnection occurs above any transfer switch XFER.

### 5. Modifications and Others

The first to fourth embodiments are not limited to the foregoing examples, but various modifications can be applied.

In the first to fourth embodiments described above, in the disconnection detection switch SW, the gate of the transistor T22 between the interconnect BLKSELn and the transistor T23 is connected to the node RDEC_SEL, but the embodiments are not limited to this case.

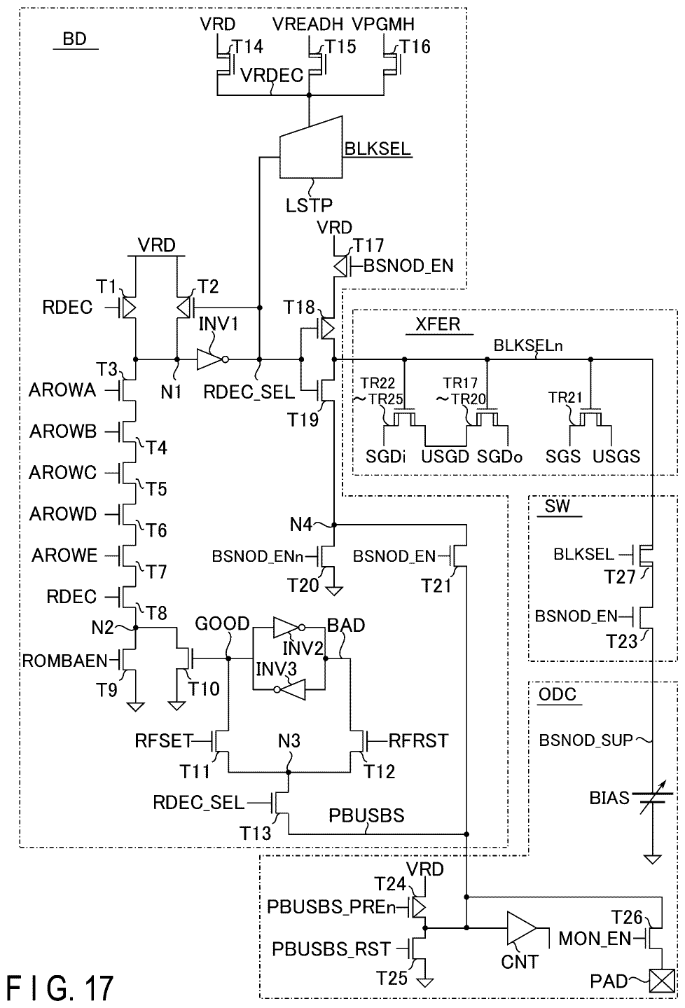

FIG. 17 is a circuit diagram showing an example of a circuit configuration of a row decoder module according to a first modification. As shown in FIG. 17, the disconnection detection switch SW may include a transistor T27 instead of the transistor T22. The transistor T27 is an N-type high withstand voltage transistor. The transistor T27 has a first end connected to the other end of the interconnect BLKSELn, a second end connected to the first end of the transistor T23, and a gate connected to the interconnect BLKSEL.

The interconnect BLKSEL extends in the region R_XFER in the X direction regardless of the presence or absence of the transistor T27. Therefore, according to the first modification, the transistor T27 makes it possible to make the length for additionally extending the interconnect connected to the gate of the transistor T27 shorter than that in the case of connecting the interconnect with the node RDEC_SEL.

In the first to fourth embodiments described above, the block decoder BD includes a bad block latch that stores the state of the block BLK, but the embodiments are not limited to this case. The block decoder BD may not include a bad block latch.

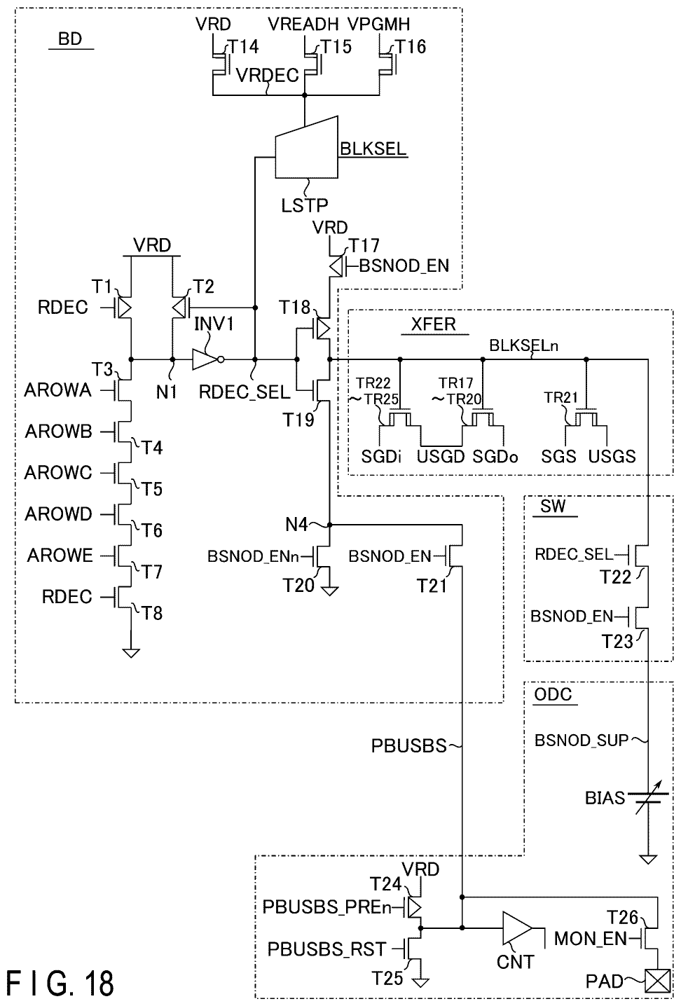

FIG. 18 is a circuit diagram showing an example of a circuit configuration of a row decoder module according to a second modification. As shown in FIG. 18, the block decoder BD may include none of transistors T9, T10, T11, T12 and T13 corresponding to the bad block latch or neither of inverters INV2 and INV3. In this case, the voltage supply to the nodes ROMBAEN, RFSET and RFRST has only to be omitted for the first to third examples of the disconnection detection operation described with reference to FIGS. 6 to 8. Accordingly, the same advantageous effects as those of the first to fourth embodiments described above can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first block including a first memory string having a first transistor at an end;
a second transistor having a first end connected to a gate of the first transistor;
a first interconnect connected to a gate of the second transistor;
a block decoder connected to one end of the first interconnect;
a third transistor having a first end connected to the other end of the first interconnect; and
a power supply connected to a second end of the third transistor.

2. The memory device of claim 1, wherein:
the block decoder and the third transistor are aligned with the second transistor in a first direction on a substrate; and
the first interconnect has a main portion that connects the block decoder and the third transistor, and the main portion includes a portion that passes above the second transistor in the first direction on the substrate.

3. The memory device of claim 2, wherein the block decoder and the third transistor are located so as to sandwich the second transistor in the first direction.

4. The memory device of claim 3, wherein the block decoder and the third transistor are adjacent to the second transistor in the first direction.

5. The memory device of claim 3, wherein:
the block decoder is separated from the second transistor in a second direction intersecting with the first direction; and
the main portion of the first interconnect further includes a portion extending in the second direction between the block decoder and the second transistor.

6. The memory device of claim 2, further comprising:
a second block including a second memory string including a fourth transistor at an end; and
a fifth transistor having a first end connected to a gate of the fourth transistor and a gate connected to the first interconnect,
wherein:
the second transistor and the fifth transistor are aligned in a second direction intersecting with the first direction on the substrate; and
the main portion of the first interconnect further includes a portion extending in the first direction so as to pass above the fifth transistor.

7. The memory device of claim 6, wherein:
the block decoder is adjacent to the second transistor and the fifth transistor in the first direction; and
the third transistor is separated from the second transistor and the fifth transistor in the first direction.

8. The memory device of claim 6, wherein:
the block decoder is separated from the second transistor and the fifth transistor in the first direction; and
the third transistor is adjacent to the second transistor and the fifth transistor in the first direction.

9. The memory device of claim 6, wherein the third transistor is located alongside the block decoder with respect to the second transistor and the fifth transistor in the first direction.

10. The memory device of claim 1, wherein the block decoder includes:
a sixth transistor and a seventh transistor each having a first end connected to the one end of the first interconnect and having different conductivity types;
an eighth transistor having a first end connected to a second end of the sixth transistor and a second end to which a first voltage is applied; and
a ninth transistor having a first end connected to a second end of the seventh transistor,
wherein the third transistor, the eighth transistor, and the ninth transistor each have a gate connected to a second interconnect.

11. The memory device of claim 10, further comprising a tenth transistor provided between the other end of the first interconnect and the first end of the third transistor,
wherein the sixth transistor, the seventh transistor, and the tenth transistor each have a gate connected to a third interconnect.

12. The memory device of claim 10, further comprising an eleventh transistor having a first end connected to the other end of the first interconnect, a second end connected to the first end of the third transistor, and a gate connected to a fourth interconnect,
wherein the block decoder includes a level shifter having an input terminal connected to a gate of the sixth transistor and a gate of the seventh transistor and an output terminal connected to the fourth interconnect.

13. The memory device of claim 10, further comprising a control circuit connected to a second end of the ninth transistor via a fifth interconnect,
wherein the control circuit is configured to determine whether the first interconnect is disconnected based on a voltage of the fifth interconnect.

14. The memory device of claim 13, wherein in an operation in which the power supply applies a second voltage that is lower than the first voltage, the control circuit is configured to determine that the first interconnect is not disconnected if the voltage of the fifth interconnect decreases from the first voltage toward the second voltage.

15. The memory device of claim 13, wherein in an operation in which the power supply applies the first voltage, the control circuit is configured to determine that the first interconnect is not disconnected if the voltage of the fifth interconnect increases from a second voltage that is lower than the first voltage toward the first voltage.

16. The memory device of claim 10, further comprising a pad connected to a second end of the ninth transistor via a fifth interconnect.

17. The memory device of claim 1, wherein:
the first memory string further includes a memory cell transistor having a gate connected to a word line; and
the first transistor connects between the memory cell transistor and a bit line at the end of the first memory string.

18. The memory device of claim 17, further comprising a twelfth transistor having a gate connected to the first interconnect;
the first memory string further includes a thirteenth transistor having a gate connected to the twelfth transistor and connecting between the memory cell transistor and a source line at an end opposite to the first transistor.

19. The memory device of claim 1, wherein the block decoder is configured to:
turn off the second transistor via the first interconnect when the first block is selected; and
turn on the second transistor via the first interconnect when the first block is not selected.

20. A memory device comprising:
a first block including a first memory string, the first memory string including a memory cell transistor having a gate connected to a word line, and a first transistor connected between the memory cell transistor and a bit line and provided at an end of the first memory string;
a second transistor having a first end connected to a gate of the first transistor;
a first interconnect connected to a gate of the second transistor;
a block decoder connected to one end of the first interconnect;
a third transistor having a first end connected to the other end of the first interconnect; and
a power supply connected to a second end of the third transistor and configured to apply a voltage to the first interconnect from the other end of the first interconnect,
wherein:
the block decoder turns off the second transistor via the first interconnect when the first block is selected; and
the block decoder turns on the second transistor via the first interconnect when the first block is not selected.
